(19) United States
(12) Patent Application Publication
(10) Pub. No.: US 2026/0333630 A1
(43) Pub. Date: Oct. 22, 2026

(54) EVAPORATION UNIT STRUCTURE

(71) Applicant: Furukawa Electric Co., Ltd., Tokyo (JP)

(72) Inventors: Hideaki KAWABATA, Tokyo (JP); Moto TAKAHASHI, Tokyo (JP); Takahiro BANZAI, Tokyo (JP); Kazunori SHIMODA, Tokyo (JP); Kunihiro DOTE, Tokyo (JP); Hirofumi AOKI, Tokyo (JP); Kenya KAWABATA, Tokyo (JP)

(73) Assignee: Furukawa Electric Co., Ltd., Tokyo (JP)

(21) Appl. No.: 19/702,772

(22) Filed: Jun. 9, 2026

Related U.S. Application Data
(63) Continuation of application No. PCT/JP2024/043313, filed on Dec. 6, 2024.

(30) Foreign Application Priority Data
Dec. 12, 2023 (JP) 2023-209698
Aug. 30, 2024 (JP) 2024-150119
Oct. 3, 2024 (JP) 2024-174563

(51) Int. Cl. H05K 7/20; F25B 39/02

(52) U.S. Cl. CPC H05K 7/20309; H05K 7/203; F25B 39/02

(57) ABSTRACT

A evaporation unit structure includes a base plate having a first surface and a second surface, the heating source immersed in the refrigerant in a liquid phase being thermally connected to the second surface, and a metal mesh stacked member thermally connected to the first surface and/or the second surface of the base plate and having a plurality of layers of a metal mesh, in which a metal wire forming the metal mesh has a flat portion.

### CROSS REFERENCE TO RELATED APPLICATIONS

The present application is a continuation application of International Patent Application No. PCT/JP2024/043313 filed on Dec. 6, 2024, which claims the benefit of Japanese Patent Application No. 2023-209698, filed on Dec. 12, 2023, Japanese Patent Application No. 2024-150119, filed on Aug. 30, 2024, and Japanese Patent Application No. 2024-174563, filed on Oct. 3, 2024. The contents of these applications are incorporated herein by reference in their entirety.

### TECHNICAL FIELD

The present disclosure relates to an evaporation unit structure for cooling a heating source (heating element) of an electrical or electronic component or the like, and more particularly to an evaporation unit structure excellent in evaporation characteristics of a refrigerant for cooling the heating source (heating element).

### DESCRIPTION OF THE RELATED ART

In association with high functionality of electronic equipment, heating elements of electrical or electronic components and the like mounted on electronic equipment have increased in heat generation amount. A temperature of a heating element of an electrical or electronic component or the like, if raised above a predetermined allowable temperature, causes the electrical or electronic component or the like to malfunction, for example. It is therefore important to maintain the temperature of the heating element of the electrical or electronic component or the like at the allowable temperature or below.

Thus, a cooling system has conventionally been used in which a heat distribution structure to which a heating element that is a cooling target is thermally connected is air-cooled to improve cooling characteristics for the heating element. Specifically, a cooling system has been proposed which includes a heat distribution structure coupled to a heat source so as to distribute heat generated by the heat source and at least one blast fan including a main blow direction, the at least one blast fan being arranged such that the main blow direction is directed toward the heat distribution structure (National Publication of International Patent Application, No. 2023-512380). In National Publication of International Patent Application, No. 2023-512380, a surface temperature of a steam chamber is lowered by blowing air toward the heat distribution structure to which the heating element is thermally connected, thereby improving cooling efficiency and/or cooling capacity and/or cooling speed of the heat distribution structure.

However, since heating elements of electronic components and the like have increased in heat generation amount year by year as described above, cooling of a heating element of an electronic component or the like is insufficient in some cases with the air-cooled cooling device that blows air with the blast fan in National Publication of International Patent Application, No. 2023-512380 or the like.

Thus, in order to cool a heating element increased in heat generation amount, it has been proposed to cool the heating element by a liquid-cooled system that immerses the heating element in a refrigerant in a liquid phase, as the refrigerant in a liquid phase has a larger heat capacity and more excellent heat transmission characteristics than a refrigerant in a gas phase, such as air. Specifically, a cooling system has been proposed which includes a cooling device having a container to which a heating element is thermally connected, a primary refrigerant in a liquid phase enclosed inside the container, and a condensation tube which extends through a gas phase portion in the container and through which a secondary refrigerant in a liquid phase flows, the heating element being immersed in the primary refrigerant in the liquid phase enclosed inside the container, and a secondary refrigerant cooling part to which the condensation tube extending from the cooling device is connected, in which the secondary refrigerant in the liquid phase flowing through the condensation tube circulates between the cooling device and the secondary refrigerant cooling part.

In the above-described liquid-cooled cooling system, the primary refrigerant in the liquid phase enclosed inside the container receives heat from the heating element to change in phase from the liquid phase to a gas phase, and the primary refrigerant changed in phase to the gas phase is changed in phase from the gas phase to the liquid phase by the condensation tube which extends through the gas phase portion inside the container and through which the secondary refrigerant in the liquid phase flows. Latent heat released from the primary refrigerant at the time of this phase change is transmitted to the secondary refrigerant in the liquid phase flowing through the condensation tube. The secondary refrigerant in the liquid phase having received the latent heat from the primary refrigerant flows through the condensation tube from the inside to the outside of the cooling device, so that the latent heat is transported to the outside of the cooling device. The secondary refrigerant having received the latent heat is cooled in the secondary refrigerant cooling part provided on the outside of the cooling device.

However, in the above-described conventional liquid-cooled cooling system, since the heating element is cooled by the latent heat through the phase change of the primary refrigerant from a liquid phase to a gas phase, there has been a need for promotion of evaporation of the primary refrigerant for further improvement in cooling characteristics. Accordingly, in the conventional liquid-cooled cooling system, there has been a need for improvement in promotion of a phase change from a liquid phase to a gas phase of a refrigerant in which a heating element that is a cooling target is immersed.

### SUMMARY

### Technical Problem

The present disclosure is related to providing an evaporation unit structure that promotes a phase change from a liquid phase to a gas phase of a refrigerant in which a heating source that is a cooling target is immersed.

A gist of a configuration of an evaporation unit structure is as follows.
{1} An evaporation unit structure including:
a base plate having a first surface and a second surface, a heating source immersed in a refrigerant in a liquid phase being thermally connected to the second surface; and
a metal mesh stacked member thermally connected to the first surface and/or the second surface of the base plate and having a plurality of layers of a metal mesh, wherein
a metal wire forming the metal mesh has a flat portion.
2} The evaporation unit structure according to {1}, wherein the flat portion of the metal wire is a pressure-welded portion of the plurality of layers of the metal mesh.
{3} The evaporation unit structure according to {1} or {2}, wherein
the metal mesh is a screen mesh in which a plurality of first metal wires forming warps and a plurality of second metal wires forming wefts alternately cross up and down, and
the plurality of first metal wires and the plurality of second metal wires have the flat portion.
{4} The evaporation unit structure according to {1} or {2}, wherein the metal mesh stacked member is sintered to be thermally connected to the base plate.
{5} The evaporation unit structure according to {1} or {2}, wherein
the first surface is opposite the second surface, and
the metal mesh stacked member is thermally connected to the first surface.
{6} The evaporation unit structure according to {1} or {2}, wherein the metal mesh stacked member is formed with a plurality of metal meshes, each being the metal mesh, stacked.
{7} The evaporation unit structure according to {1} or {2}, wherein a mesh number of the metal mesh forming the metal mesh stacked member is 200/2.54 cm or more.
{8} The evaporation unit structure according to {1} or {2}, wherein a mesh number of the metal mesh forming the metal mesh stacked member is 300/2.54 cm or more.
{9} The evaporation unit structure according to {1} or {2}, wherein the metal mesh stacked member is formed by two or more layers and ten or less layers of the metal mesh.
{10} The evaporation unit structure according to {1} or {2}, wherein the metal mesh stacked member or a plurality of metal mesh stacked members, each being the metal mesh stacked member, is/are provided along an extending direction of the first surface.
{11} The evaporation unit structure according to {1} or {2}, wherein the metal mesh stacked member or a plurality of metal mesh stacked members, each being the metal mesh stacked member, is/are provided along an extending direction of the second surface.
{12} The evaporation unit structure according to {1} or {2}, wherein the base plate is a vapor chamber including a container in which a cavity portion is formed inside, a working fluid enclosed in the cavity portion, and a vapor flow path which is provided in the cavity portion and through which the working fluid in a gas phase flows.

In an aspect of the evaporation unit structure of the above-described {1}, heat is transmitted from the heating source immersed in the refrigerant in the liquid phase to the second surface of the base plate, and the heat transmitted to the second surface of the base plate is transmitted to the metal mesh stacked member thermally connected to the base plate. The heat transmitted to the metal mesh stacked member is transmitted to the refrigerant in the liquid phase in contact with the metal mesh stacked member, and the refrigerant in the liquid phase changes in phase to a gas phase in a section in contact with the metal mesh stacked member. Since the refrigerant in the liquid phase changes in phase to the gas phase in the section in contact with the metal mesh stacked member, the heating source immersed in the refrigerant in the liquid phase is cooled.

According to an aspect of the evaporation unit structure of the present disclosure, because of including a base plate having a first surface and a second surface, a heating source immersed in a refrigerant in a liquid phase being thermally connected to the second surface, and a metal mesh stacked member thermally connected to the first surface and/or the second surface of the base plate and having a plurality of layers of a metal mesh, in which a metal wire forming the metal mesh has a flat portion, an area of contact with the refrigerant in which the heating source is immersed increases in the metal mesh stacked member, so that a heat radiation area increases, and many fine pore portions that are advantageous in generating air bubbles composed of the refrigerant in a gas phase are present, so that an amount of generation of the air bubbles increases. Accordingly, according to the aspect of the evaporation unit structure of the present disclosure, it is possible to promote a phase change from a liquid phase to a gas phase of the refrigerant in which the heating source, which is a cooling target, is immersed, and as a result, cooling characteristics for the heating source immersed in the refrigerant in the liquid phase are improved.

According to an aspect of the evaporation unit structure of the present disclosure, the flat portion of the metal wire forming the metal mesh is a pressure-welded portion of the plurality of layers of the metal mesh. Therefore, the fine pore portions, which are advantageous in generating air bubbles composed of the refrigerant in a gas phase, are reliably formed in the metal mesh stacked member while reliably joining the plurality of layers of the metal mesh.

According to an aspect of the evaporation unit structure of the present disclosure, the metal mesh is a screen mesh in which a plurality of first metal wires forming warps and a plurality of second metal wires forming wefts alternately cross up and down, and the plurality of first metal wires and the plurality of second metal wires have the flat portion. Therefore, the fine pore portions, which are advantageous in generating air bubbles composed of the refrigerant in a gas phase, are reliably formed throughout the entire metal mesh stacked member.

According to an aspect of the evaporation unit structure of the present disclosure, the metal mesh stacked member is sintered to be thermally connected to the base plate. Therefore, thermal connection characteristics between the metal mesh stacked member and the base plate are improved.

According to an aspect of the evaporation unit structure of the present disclosure, the metal mesh stacked member is formed with a plurality of metal meshes, each being the metal mesh, stacked. Therefore, a diameter and a shape of the fine pore portions in the metal mesh stacked member can be easily adjusted, and efficiency of manufacturing the metal mesh stacked member is improved.

According to an aspect of the evaporation unit structure of the present disclosure, since the mesh number of the metal mesh forming the metal mesh stacked member is 200/2.54 cm or more, the fine pore portions, which are advantageous in generating air bubbles composed of the refrigerant in a gas phase, are reliably formed.

According to an aspect of the evaporation unit structure of the present disclosure, since the mesh number of the metal mesh forming the metal mesh stacked member is 300/2.54 cm or more, the fine pore portions, which are advantageous in generating air bubbles composed of the refrigerant in a gas phase, are more reliably formed, and a larger number of the fine pore portions are formed.

According to an aspect of the evaporation unit structure of the present disclosure, since the metal mesh stacked member is formed by two or more layers and ten or less layers of the metal mesh, the fine pore portions, which are advantageous in generating air bubbles composed of the refrigerant in a gas phase, are reliably formed, and the air bubbles composed of the refrigerant in the gas phase can smoothly move away from the metal mesh stacked member.

According to an aspect of the evaporation unit structure of the present disclosure, since the base plate is a vapor chamber, the function of diffusing heat can be improved.

### BRIEF DESCRIPTION OF THE DRAWINGS

FIG. 1 is a side view explaining an outline of an evaporation unit structure according to a first embodiment example of the present disclosure;

FIG. 2 is a perspective view explaining the outline of the evaporation unit structure according to the first embodiment example of the present disclosure;

FIG. 3 is a plan view explaining the outline of the evaporation unit structure according to the first embodiment example of the present disclosure;

FIG. 4 is an explanatory view illustrating an outline of flat portions of the evaporation unit structure according to the first embodiment example of the present disclosure;

FIG. 5 is an explanatory view illustrating an outline of a metal mesh stacked member of the evaporation unit structure according to the first embodiment example of the present disclosure;

FIG. 6 is an explanatory view illustrating a usage of the evaporation unit structure according to the first embodiment example of the present disclosure;

FIG. 7 is an explanatory view illustrating an outline of positioning of a base plate and metal meshes in a method for manufacturing the evaporation unit structure according to the first embodiment example of the present disclosure;

FIG. 8 is a plan view explaining an outline of an evaporation unit structure according to a second embodiment example of the present disclosure;

FIG. 9 is a side view explaining the outline of the evaporation unit structure according to the second embodiment example of the present disclosure;

FIG. 10 is a plan view explaining an outline of an evaporation unit structure according to a third embodiment example of the present disclosure;

FIG. 11 is a side view explaining the outline of the evaporation unit structure according to the third embodiment example of the present disclosure;

FIG. 12 is a plan view explaining an outline of an evaporation unit structure according to a fourth embodiment example of the present disclosure;

FIG. 13 is a side view explaining the outline of the evaporation unit structure according to the fourth embodiment example of the present disclosure;

FIG. 14 is a plan view explaining an outline of an evaporation unit structure according to a fifth embodiment example of the present disclosure;

FIG. 15 is a side view explaining the outline of the evaporation unit structure according to the fifth embodiment example of the present disclosure;

FIG. 16 is a plan view explaining an outline of an evaporation unit structure according to a sixth embodiment example of the present disclosure;

FIG. 17 is a side view explaining the outline of the evaporation unit structure according to the sixth embodiment example of the present disclosure;

FIG. 18 is an explanatory view illustrating another usage of the evaporation unit structure according to the first embodiment example of the present disclosure;

FIG. 19 is a plan view explaining an outline of another usage in another embodiment example of the evaporation unit structure of the present disclosure;

FIG. 20 is a side view explaining the outline of the other usage in the other embodiment example of the evaporation unit structure of the present disclosure;

FIG. 21 is a side view explaining an outline of an evaporation unit structure obtained by modifying the first embodiment example of the present disclosure;

FIG. 22 is a side view explaining an outline of an evaporation unit structure obtained by modifying the fourth embodiment example of the present disclosure;

FIG. 23 is a side view explaining an outline of an evaporation unit structure obtained by modifying the sixth embodiment example of the present disclosure;

FIG. 24 is a side view explaining an outline of an evaporation unit structure according to a seventh embodiment example of the present disclosure;

FIG. 25 is a perspective view explaining the outline of the evaporation unit structure according to the seventh embodiment example of the present disclosure;

FIG. 26 is a plan view explaining the outline of the evaporation unit structure according to the seventh embodiment example of the present disclosure;

FIG. 27 is an explanatory view illustrating a usage of the evaporation unit structure according to the seventh embodiment example of the present disclosure;

FIG. 28 is a side view explaining an outline of an evaporation unit structure according to an eighth embodiment example of the present disclosure;

FIG. 29 is a side view explaining an outline of an evaporation unit structure according to a ninth embodiment example of the present disclosure;

FIG. 30 is a side view explaining an outline of an evaporation unit structure according to a tenth embodiment example of the present disclosure;

FIG. 31 is an enlarged side view explaining an outline of a boiling promoting part in the evaporation unit structure according to the tenth embodiment example of the present disclosure;

FIG. 32 is a side view explaining an outline of an evaporation unit structure according to an eleventh embodiment example of the present disclosure;

FIG. 33 is a side view explaining an outline of an evaporation unit structure according to a twelfth embodiment example of the present disclosure; and

FIG. 34 is a side view explaining an outline of an evaporation unit structure according to another embodiment example of the present disclosure.

### DETAILED DESCRIPTION

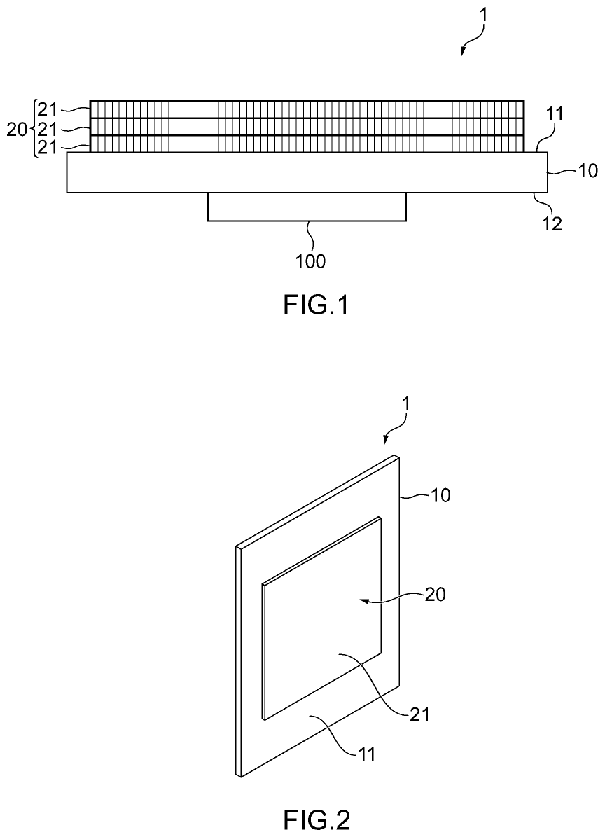

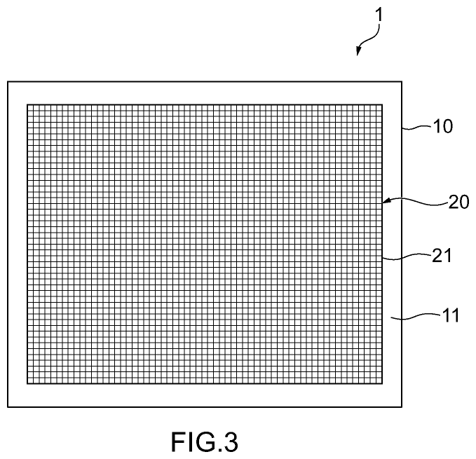

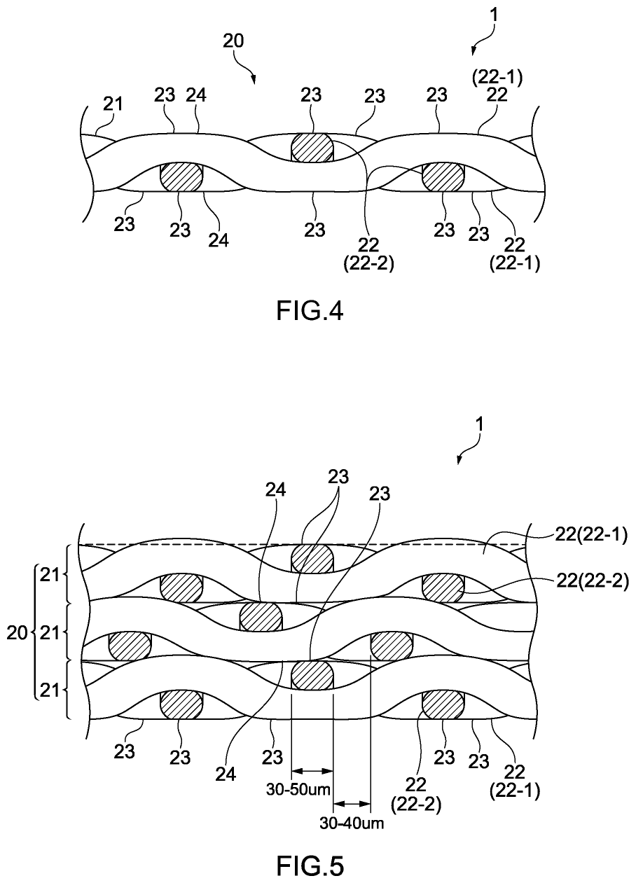

Hereinafter, an evaporation unit structure according to a first embodiment example of the present disclosure will be described using the accompanying drawings. Note that FIG. 1 is a side view explaining an outline of the evaporation unit structure according to the first embodiment example of the present disclosure. FIG. 2 is a perspective view explaining the outline of the evaporation unit structure according to the first embodiment example of the present disclosure. FIG. 3 is a plan view explaining the outline of the evaporation unit structure according to the first embodiment example of the present disclosure. FIG. 4 is an explanatory view illustrating an outline of flat portions of the evaporation unit structure according to the first embodiment example of the present disclosure. FIG. 5 is an explanatory view illustrating an outline of a metal mesh stacked member of the evaporation unit structure according to the first embodiment example of the present disclosure.

As illustrated in FIGS. 1, 2, and 3, an evaporation unit structure 1 according to the first embodiment example of the present disclosure includes a base plate 10 having a first surface 11 and a second surface 12, and a metal mesh stacked member 20 thermally connected to the first surface 11 and/or the second surface 12 of the base plate 10 and having a plurality of layers of the metal meshes 21. A heating source 100 immersed in a refrigerant in a liquid phase (not illustrated in FIGS. 1 to 3) is thermally connected to the second surface 12 of the base plate 10. In the evaporation unit structure 1, the metal mesh stacked member 20 is provided on the first surface 11 of the base plate 10. That is, in the evaporation unit structure 1, the metal mesh stacked member 20 is thermally connected to the first surface 11 of the base plate 10.

In the base plate 10 of the evaporation unit structure 1, the first surface 11 is opposite the second surface 12, and the metal mesh stacked member 20 is thermally connected to the first surface 11. From the foregoing, the metal mesh stacked member 20 is arranged opposite the heating source 100 with the base plate 10 interposed therebetween. Note that in the evaporation unit structure 1, the metal mesh stacked member 20 is not provided on the second surface 12 of the base plate 10, and accordingly, the metal mesh stacked member 20 is not thermally connected to the second surface 12 of the base plate 10.

The base plate 10 has a longitudinal direction and a width direction. The base plate 10 is not particularly limited in shape, but in the evaporation unit structure 1, is a plate-like member having a predetermined thickness and has a rectangular shape in a plan view. The first surface 11 forms a first main surface of the base plate 10, and the second surface 12 forms a second main surface of the base plate 10.

The base plate 10 is a member that thermally connects the heating source 100 to the evaporation unit structure 1 to transmit heat of the heating source 100 from the heating source 100 to the metal mesh stacked member 20. It is preferable that the base plate 10 should be a solid plate-like member from a viewpoint of heat transmission characteristics.

The base plate 10 is not particularly limited in material, and metals such as copper, a copper alloy, aluminum, an aluminum alloy, nickel, a nickel alloy, stainless steel, titanium, and a titanium alloy, for example, can be cited. Further, dimensions of the base plate 10 are properly selectable according to use conditions or the like of the evaporation unit structure 1, and a plate-like member which is 40 mm or more and 120 mm or less in the longitudinal direction (the X-direction) by 40 mm or more and 120 mm or less in the width direction (the Y-direction) by 4 mm or more and 5 mm or less in the thickness direction (the Z-direction), for example, is cited.

The metal mesh stacked member 20 has a stacked structure in which a plurality of metal meshes 21, 21, 21, . . . are stacked in the thickness direction of the base plate 10. Further, the metal mesh stacked member 20 has a structure in which the plurality of metal meshes 21, 21, 21, . . . are stacked in the thickness direction of the metal meshes 21. A stack number of the metal meshes 21 of the metal mesh stacked member 20 is not particularly limited so long as there are a plurality of layers which are two or more layers, and the metal mesh stacked member 20 of the evaporation unit structure 1 has a stacked structure composed of three layers of the metal meshes 21.

Each of the metal meshes 21 forming the metal mesh stacked member 20 has a longitudinal direction and a width direction. Each of the metal meshes 21 is not particularly limited in shape, but in the evaporation unit structure 1, is a sheet-like member having a predetermined thickness and has a rectangular shape in a plan view.

From the foregoing, the metal mesh stacked member 20 has a longitudinal direction and a width direction. The metal mesh stacked member 20 is not particularly limited in shape, but in the evaporation unit structure 1, is a plate-like member having a predetermined thickness and has a rectangular shape in a plan view. Because of having the structure in which the plurality of metal meshes 21, 21, 21, . . . are stacked in the thickness direction of the metal meshes 21, the metal mesh stacked member 20 is not a solid plate-like member, but is a plate-like member in which many fine pore portions are present.

As illustrated in FIGS. 1, 2, and 3, the metal mesh stacked member 20 extends along an extending direction of the first surface 11 of the base plate 10. Further, in the evaporation unit structure 1, the single metal mesh stacked member 20 is provided along the extending direction of the first surface 11 of the base plate 10.

As illustrated in FIG. 4, in the metal mesh stacked member 20 of the evaporation unit structure 1, metal wires 22 forming the metal mesh 21 have flat portions 23. The flat portion 23 is a site having a flat shape along the extending direction of the metal mesh 21, that is, along a planar direction of the metal mesh 21, in the metal wire 22 forming the metal mesh 21. Further, the flat portion 23 has a smooth surface along the extending direction of the metal mesh 21.

As illustrated in FIG. 5, in the evaporation unit structure 1, the stacked plurality of metal meshes 21, 21, 21, . . . are pressure-welded, so that the plurality of metal meshes 21, 21, 21, . . . are closely stacked. In the evaporation unit structure 1, the stacked three metal meshes 21, 21, 21, . . . are pressure-welded, so that a three-layer structure in which the three metal meshes 21, 21, 21, . . . are closely stacked is obtained. From the foregoing, the metal mesh stacked member 20 has the structure in which the plurality of metal meshes 21, 21, 21, . . . are pressure-welded to be closely stacked. Further, the flat portions 23 of the metal wires 22 forming the metal meshes 21 are pressure-welded portions 24 of the plurality of layers of metal meshes 21, 21, 21, . . . as illustrated in FIGS. 4 and 5. That is, the flat portion 23 of the metal mesh 21 is the pressure-welded portion 24 in contact with another metal mesh 21 adjacent in the thickness direction of the metal mesh stacked member 20. Accordingly, the flat portions 23 are formed in each of the plurality of layers of metal meshes 21, 21, 21, . . . . In particular, the flat portions 23 are formed in sites where the stacked plurality of metal meshes 21, 21, 21 are in contact with one another, sites in contact with the base plate 10 in the metal mesh stacked member 20, and sites of the metal wires 22 having protruded in the thickness direction of the metal meshes 21, on an outer surface of the metal mesh stacked member 20.

The metal mesh 21 is a screen mesh in which a plurality of first metal wires 22-1, 22-1, 22-1, . . . forming warps and a plurality of second metal wires 22-2, 22-2, 22-2, . . . forming wefts alternately cross up and down. In the evaporation unit structure 1, the plurality of first metal wires 22-1, 22-1, 22-1, . . . and the plurality of second metal wires 22-2, 22-2, 22-2, . . . each have the flat portions 23. Accordingly, the metal mesh stacked member 20 is provided with the flat portions 23 throughout an entire planar direction of the metal mesh stacked member 20.

A distance between the metal wires 22 of the metal mesh 21 forming the metal mesh stacked member 20 (a size of an opening, which is a size of a clearance between the metal wires 22) is 30 μm or more and 40 μm or less, for example, and a wire diameter of the metal wire 22 of the metal mesh 21 forming the metal mesh stacked member 20 is 30 μm or more and 50 μm or less, for example. Further, a void area of the metal mesh stacked member 20 is 900 μm² or more and 1600 μm² or less, for example.

When the flat portions 23 are formed on the metal wires 22 as described above, a pitch between the metal wires 22 (an interval between central lines of the metal wires 22) hardly changes as compared with the pitch in a state before formation (before pressure welding), whereas the wire diameter of the metal wires 22 becomes larger, and the distance between the metal wires 22 becomes smaller. Herein, assume that a value obtained by dividing the wire diameter of the metal wires 22 by the pitch between the metal wires 22 is α (<1). By forming the flat portions 23 by pressure welding, the value of a becomes larger. An example of changes in respective dimensions before and after pressure welding in a case of a mesh number #350 is shown in Table 1.

TABLE 1

| | | After Pressure Welding | |
|---|---|---|---|
| | Before Pressure | Minimum | Maximum |
| | Welding | Value | Value |
| Wire Diameter (μm) | 27 | 28 | 30 |
| Pitch (μm) | 73 | 73 | 73 |
| α | 0.37 | 0.39 | 0.41 |

As described above, in the case of the mesh number #350, the value of a changes from 0.37 before compression to 0.39-0.41 after compression, for example. That is, the value of a becomes larger by approximately 5-11%, for example, by pressure welding.

As illustrated in FIGS. 1, 2, and 3, in the evaporation unit structure 1, the metal mesh stacked member 20 is sintered to be integrated with the base plate 10 and to be thermally connected to the base plate 10. Further, in the evaporation unit structure 1, the metal mesh stacked member 20 is sintered, so that the stacked plurality of metal meshes 21, 21, 21, . . . are integrated.

In the evaporation unit structure 1, the metal mesh stacked member 20 is formed with the plurality of metal meshes 21, 21, 21, . . . stacked. That is, the plurality of metal meshes 21, 21, 21, . . . which are separate elements are pressure-welded in the stacked state, so that the plurality of metal meshes 21, 21, 21, . . . are closely stacked. Further, the plurality of metal meshes 21, 21, 21, . . . , which are separate elements, are sintered in the stacked state, so that the stacked plurality of metal meshes 21, 21, 21, . . . are integrated. From the foregoing, the metal mesh stacked member 20 of the evaporation unit structure 1 is in an aspect different from a stacked structure formed by folding a single metal mesh. Further, in the metal mesh stacked member 20, since the plurality of metal meshes 21, 21, 21, . . . are integrated in the closely stacked state, the metal mesh stacked member 20 has excellent heat conductive characteristics even if formed with the plurality of metal meshes 21, 21, 21, . . . stacked.

The mesh number of the metal meshes 21 forming the metal mesh stacked member 20 is not particularly limited, but in the evaporation unit structure 1, the plurality of first metal wires 22-1, 22-1, 22-1, . . . forming warps and the plurality of second metal wires 22-2, 22-2, 22-2, . . . forming wefts each have a mesh number of 200/2.54 cm or more, and more specifically, a mesh number of 300/2.54 cm or more. From the foregoing, the metal mesh stacked member 20 is in an aspect in which many fine pore portions are present. An upper limit value of the mesh number of the metal meshes 21 forming the metal mesh stacked member 20 is not particularly limited, but 500/2.54 cm is cited for both of the plurality of first metal wires 22-1, 22-1, 22-1, . . . forming warps and the plurality of second metal wires 22-2, 22-2, 22-2, . . . forming wefts, for example.

As to the mesh number of the respective metal meshes 21 forming the metal mesh stacked member 20, the respective metal meshes 21 may have the same mesh number, or may have different mesh numbers. In the evaporation unit structure 1, the respective metal meshes 21 have the same mesh number for ease of description.

The metal meshes 21 is not particularly limited in material, and copper, a copper alloy, aluminum, an aluminum alloy, nickel, a nickel alloy, stainless steel, titanium, a titanium alloy, and the like, for example, can be cited. Further, dimensions of the metal mesh stacked member 20 are properly selectable according to the use conditions or the like of the evaporation unit structure 1, and a plate-like member of 30 mm or more and 110 mm or less in the longitudinal direction (the X-direction) by 30 mm or more and 110 mm or less in the width direction (the Y-direction) by 0.06 mm or more and 0.6 mm or less in the thickness direction (the Z-direction), for example, is cited.

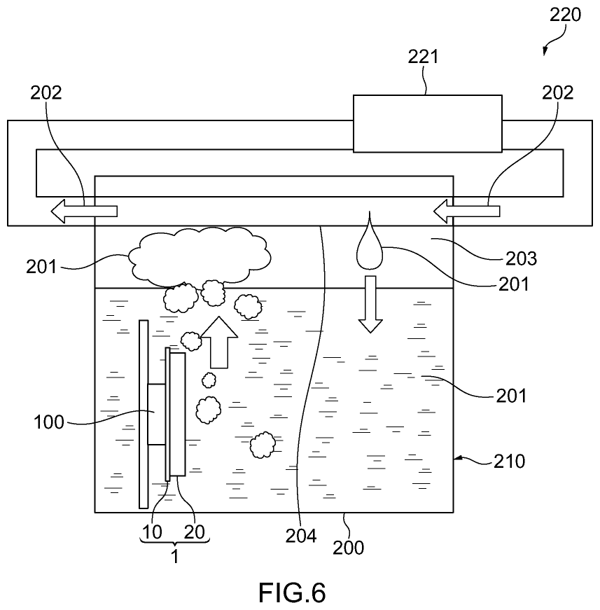

Next, a usage example of the evaporation unit structure 1 according to the first embodiment example of the present disclosure will be described. FIG. 6 is an explanatory view illustrating a usage of the evaporation unit structure according to the first embodiment example of the present disclosure.

As illustrated in FIG. 6, the evaporation unit structure 1 can be used in a cooling system 220 including a cooling device 210 having a container 200 to which the heating source 100 is thermally connected, a primary refrigerant 201 in a liquid phase enclosed and retained inside the container 200, and a condensation tube 204 which extends through a gas phase portion 203 inside the container 200 and through which a secondary refrigerant 202 in a liquid phase flows, the heating source 100 being immersed in the primary refrigerant 201 in the liquid phase enclosed inside the container 200, and a secondary refrigerant cooling part 221 to which the condensation tube 204 extending from the cooling device 210 is connected, in which the secondary refrigerant 202 in the liquid phase flowing through the condensation tube 204 circulates between the cooling device 210 and the secondary refrigerant cooling part 221. Specifically, a usage of thermally connecting the evaporation unit structure 1 according to the first embodiment example of the present disclosure in the state immersed in the primary refrigerant 201 in the liquid phase to the heating source 100 immersed in the primary refrigerant 201 in the liquid phase is cited.

In the usage example of the above-described evaporation unit structure 1, the evaporation unit structure 1 receives heat from the heating source 100, and the primary refrigerant 201 in the liquid phase enclosed and retained inside the container 200 receives the heat originating from the heating source 100 from the evaporation unit structure 1, so that the primary refrigerant 201 in the liquid phase changes in phase from the liquid phase to a gas phase in a section in contact with the evaporation unit structure 1. More specifically, the base plate 10 of the evaporation unit structure 1 transmits heat of the heating source 100 from the heating source 100 to the metal mesh stacked member 20, and the heat transmitted to the metal mesh stacked member 20 is transmitted from the metal mesh stacked member 20 to the primary refrigerant 201 in the liquid phase in contact with the metal mesh stacked member 20, so that the primary refrigerant 201 in the liquid phase changes in phase to a gas phase in the section in contact with the metal mesh stacked member 20 to cause many air bubbles of the primary refrigerant 201 to be formed. Since the primary refrigerant 201 in the liquid phase changes in phase to the gas phase in the section in contact with the metal mesh stacked member 20 to cause air bubbles of the primary refrigerant 201 to be formed, the heating source 100 immersed in the primary refrigerant 201 in the liquid phase is cooled.

The air bubbles of the primary refrigerant 201 generated in the section in contact with the metal mesh stacked member 20 move on to the gas phase portion 203 inside the container 200 away from the metal mesh stacked member 20, and the primary refrigerant 201 is changed in phase from a gas phase to a liquid phase by the condensation tube 204, which extends through the gas phase portion 203 inside the container 200 and through which the secondary refrigerant 202 in the liquid phase flows. Latent heat released from the primary refrigerant 201 at the time of this phase change is transmitted to the secondary refrigerant 202 in the liquid phase flowing through the condensation tube 204. The secondary refrigerant 202 in the liquid phase having received the latent heat from the primary refrigerant 201 flows through the condensation tube 204 from the inside to the outside of the cooling device 210, so that the latent heat is transported to the outside of the cooling device 210. The secondary refrigerant 202 having received the latent heat is cooled in the secondary refrigerant cooling part 221 provided on the outside of the cooling device 210. The primary refrigerant 201 changed in phase from the gas phase to the liquid phase by the condensation tube 204, through which the secondary refrigerant 202 in the liquid phase flows, drops from the condensation tube 204 to the primary refrigerant 201 in the liquid phase retained inside the container 200.

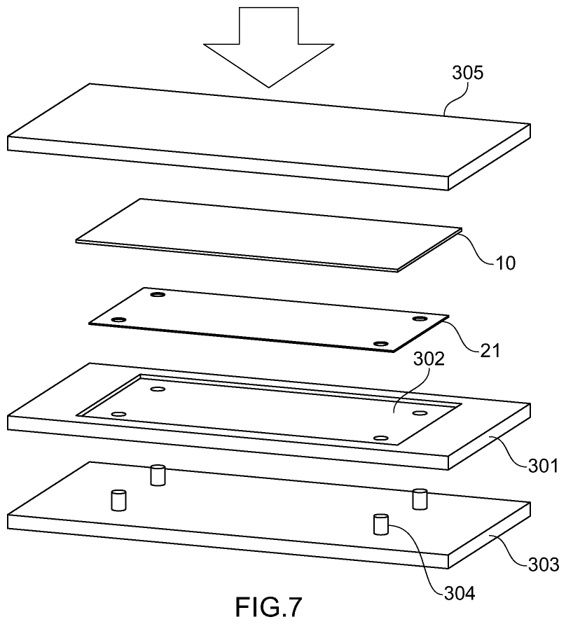

Next, an example of a method for manufacturing the evaporation unit structure 1 according to the first embodiment example of the present disclosure will be described. FIG. 7 is an explanatory view illustrating an outline of positioning of the base plate and metal meshes in the method for manufacturing the evaporation unit structure according to the first embodiment example of the present disclosure.

First, the three metal meshes 21 are pressure-welded in an overlapped state. By pressure-welding the three metal meshes 21, the three layers of metal meshes 21 are closely stacked, and the flat portions 23 are formed on the metal wires 22 forming the metal meshes 21. Further, by being pressure-welded, the three metal meshes 21 are reduced in dimension in the thickness direction (the Z-direction) as compared with the dimension before pressure welding. As a pressure for the pressure welding, 10 MPa or more and 60 MPa or less, for example, is cited. Thereafter, as illustrated in FIG. 7, the base plate 10 and the pressure-welded three metal meshes 21 are placed in an overlapped state on a recessed positioning portion 302 provided in a flat plate-like positioning jig 301, and a flat plate-like pin jig 303 having pins 304 provided in a standing manner is attached to a downside of the positioning jig 301 to fix the base plate 10 and the pressure-welded three metal meshes 21 onto the positioning portion 302 with the pins 304. By the above-described method, the base plate 10 and the pressure-welded three metal meshes 21 are positioned. At this time, the base plate 10 shall be located upward in the direction of gravity, and the pressure-welded three metal meshes 21 shall be located downward in the direction of gravity. Thereafter, a flat plate-like weight 305 is placed on the base plate 10 and the pressure-welded three metal meshes 21, thereby interposing the base plate 10 and the three metal meshes 21 between the weight 305 and the positioning jig 301. At this time, fixation stability of the base plate 10 and the pressure-welded three metal meshes 21 on the positioning portion 302 is improved by a stress imposed by the weight 305 toward the positioning jig 301.

Thereafter, the base plate 10 and the pressure-welded three metal meshes 21 in the state interposed between the weight 305 and the positioning jig 301 are reversed in an up-down direction, so that the base plate 10 is located downward in the direction of gravity, and the pressure-welded three metal meshes 21 are located upward in the direction of gravity. Thereafter, the positioning jig 301 and the pin jig 303 are removed to bring a state in which the base plate 10 and the pressure-welded three metal meshes 21 are placed on the weight 305. Thereafter, a weight for sintering is put on the base plate 10 and the pressure-welded three metal meshes 21, which are placed on the weight 305, and sintering treatment on the base plate 10 and the pressure-welded three metal meshes 21 is performed in the state in which the base plate 10 and the pressure-welded three metal meshes 21 are interposed between the weight 305 and the weight for sintering. By performing the sintering treatment on the base plate 10 and the pressure-welded three metal meshes 21, the stacked three metal meshes 21 are integrated to form the metal mesh stacked member 20. Further, by performing the sintering treatment on the base plate 10 and the pressure-welded three metal meshes 21, the evaporation unit structure 1 can be manufactured in which the metal mesh stacked member 20 is integrated with the base plate 10, so that the metal mesh stacked member 20 is thermally connected to the base plate 10. Note that as a temperature for the sintering treatment, 900 °C or more and 950 °C or less, for example, is cited.

In the aspect of the evaporation unit structure 1, because of including the base plate 10 having the first surface 11 and the second surface 12, the heating source 100 immersed in the refrigerant in a liquid phase (for example, the primary refrigerant 201 in the cooling device 210) being thermally connected to the second surface 12, and the metal mesh stacked member 20 thermally connected to the first surface 11 of the base plate 10 and having a plurality of layers of the metal meshes 21, in which the metal wires 22 forming the metal meshes 21 have the flat portions 23, an area of contact with the refrigerant (the primary refrigerant 201 in the cooling device 210) in which the heating source 100 is immersed increases in the metal mesh stacked member 20, so that a heat radiation area of the metal mesh stacked member 20 increases, and many fine pore portions that are advantageous in generating air bubbles composed of the refrigerant in a gas phase (the primary refrigerant 201 in the cooling device 210) are present in the metal mesh stacked member 20, so that an amount of generation of the air bubbles increases. Accordingly, in the evaporation unit structure 1, it is possible to promote a phase change from a liquid phase to a gas phase of the refrigerant in the liquid phase (the primary refrigerant 201 in the cooling device 210) in which the heating source 100 that is a cooling target is immersed, and as a result, cooling characteristics for the heating source 100 immersed in the refrigerant in the liquid phase (the primary refrigerant 201 in the cooling device 210) are improved.

Further, in the aspect of the evaporation unit structure 1, since the flat portions 23 of the metal wires 22 forming the metal meshes 21 are the pressure-welded portions 24 of the plurality of layers of metal meshes 21, 21, 21, . . . , the plurality of layers of metal meshes 21, 21, 21, . . . are reliably joined, and the fine pore portions, which are advantageous in generating air bubbles composed of the refrigerant in a gas phase (the primary refrigerant 201 in the cooling device 210), are reliably formed in the metal mesh stacked member 20.

Further, in the aspect of the evaporation unit structure 1, since the metal mesh 21 is a screen mesh in which the plurality of first metal wires 22-1, 22-1, 22-1, . . . forming warps and the plurality of second metal wires 22-2, 22-2, 22-2, . . . forming wefts alternately cross up and down, and the plurality of first metal wires 22-1, 22-1, 22-1, . . . and the plurality of second metal wires 22-2, 22-2, 22-2, . . . have the flat portions 23, the fine pore portions, which are advantageous in generating air bubbles composed of the refrigerant in a gas phase (the primary refrigerant 201 in the cooling device 210), are reliably formed throughout the entire metal mesh stacked member 20.

Further, in the aspect of the evaporation unit structure 1, the metal mesh stacked member 20 is sintered to be thermally connected to the base plate 10. Therefore, the thermal connection characteristics between the metal mesh stacked member 20 and the base plate 10 are improved.

Further, in the aspect of the evaporation unit structure 1, since the metal mesh stacked member 20 is formed with the plurality of metal meshes 21, 21, 21, . . . stacked, the diameter and shape of the fine pore portions in the metal mesh stacked member 20 can be easily adjusted, and efficiency of manufacturing the metal mesh stacked member 20, and in turn, the evaporation unit structure 1, is improved.

Further, in the aspect of the evaporation unit structure 1, since the mesh number of the metal meshes 21 forming the metal mesh stacked member 20 is 200/2.54 cm or more, the fine pore portions, which are advantageous in generating air bubbles composed of the refrigerant in a gas phase (the primary refrigerant 201 in the cooling device 210), are reliably formed.

Further, in the aspect of the evaporation unit structure 1, since the mesh number of the metal meshes 21 forming the metal mesh stacked member 20 is 300/2.54 cm or more, the fine pore portions, which are advantageous in generating air bubbles composed of the refrigerant in a gas phase (the primary refrigerant 201 in the cooling device 210), are more reliably formed, and a larger number of the fine pore portions are formed.

Further, in the aspect of the evaporation unit structure 1, since the flat portions 23 are formed on the metal wires 22, an area (ratio) of a flat region on a surface of the metal mesh 21 becomes larger than in a case in which flat portions are not formed. Since such metal meshes 21 are stacked, the area of contact between the overlapped metal meshes 21 becomes larger, so that contact thermal resistance can be made smaller. Further, the area of contact between a surface (the first surface 11 in the present embodiment) of the base plate 10 and a surface (a surface of the metal mesh 21 provided closest to the first surface 11) of the metal mesh stacked member 20 also becomes larger, so that contact thermal resistance can be made smaller.

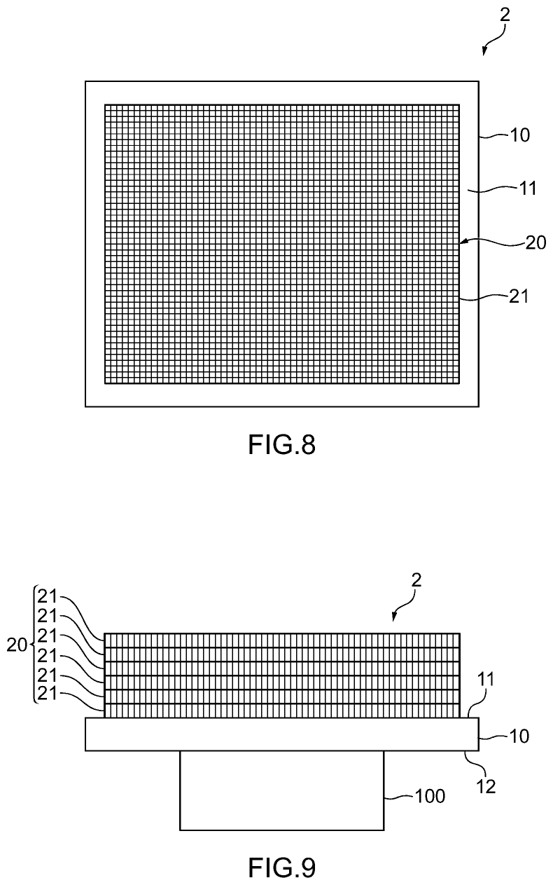

Next, an evaporation unit structure according to a second embodiment example of the present disclosure will be described using the accompanying drawings. Since the evaporation unit structure according to the second embodiment example has main components in common with the evaporation unit structure according to the first embodiment example, same components as the components of the evaporation unit structure according to the first embodiment example are described by using the same reference signs. Note that FIG. 8 is a plan view explaining an outline of the evaporation unit structure according to the second embodiment example of the present disclosure. FIG. 9 is a side view explaining the outline of the evaporation unit structure according to the second embodiment example of the present disclosure.

The metal mesh stacked member 20 of the evaporation unit structure 1 according to the first embodiment example has the stacked structure composed of three layers of the metal meshes 21, but instead of this, in an evaporation unit structure 2 according to the second embodiment example, the metal mesh stacked member 20 has a stacked structure composed of six layers of the metal meshes 21 as illustrated in FIGS. 8 and 9. That is, the evaporation unit structure 2 is in an aspect in which the stack number of the metal meshes 21 forming the metal mesh stacked member 20 is larger than the stack number of the metal meshes 21 forming the metal mesh stacked member 20 of the evaporation unit structure 1. As described, the stack number of the metal meshes 21 forming the metal mesh stacked member 20 is not particularly limited so long as there are two or more layers, and is properly selectable according to use conditions or the like of the evaporation unit structure of the present disclosure.

As described above, the stack number of the metal meshes 21 forming the metal mesh stacked member 20 is not particularly limited, but is two or more layers and preferably three or more layers from a viewpoint of reliably forming the fine pore portions, which are advantageous in generating air bubbles composed of the refrigerant in a gas phase. On the other hand, it is preferable that the stack number of the metal meshes 21 forming the metal mesh stacked member 20 should be fifteen or less layers, and ten or less layers are particularly preferable from a viewpoint of enabling the air bubbles composed of the refrigerant in a gas phase to smoothly move away from the metal mesh stacked member 20 and from a viewpoint of ensuring close contact among the plurality of metal meshes 21, 21, 21, . . . forming the metal mesh stacked member 20 to prevent heat conductive characteristics from degrading in the entire metal mesh stacked member 20. From the foregoing, it is preferable that the metal mesh stacked member 20 should be formed by two or more layers and fifteen or less layers of the metal meshes 21. Note that a preferable upper limit value of the stack number of the metal meshes 21 may vary according to heat generation density or the like of a heating source to be thermally connected to the evaporation unit structure of the present disclosure.

Note that also in the evaporation unit structure 2, the metal mesh stacked member 20 is formed with the six metal meshes 21, 21, 21, . . . stacked. That is, the six metal meshes 21, 21, 21, . . . , which are separate elements, are pressure-welded in the stacked state, so that the six metal meshes 21, 21, 21, . . . are closely stacked.

Also in the aspect of the evaporation unit structure 2, because of including the base plate 10 having the first surface 11 and the second surface 12, the heating source 100 immersed in the refrigerant in a liquid phase (for example, the primary refrigerant 201 in the cooling device 210) being thermally connected to the second surface 12, and the metal mesh stacked member 20 thermally connected to the first surface 11 of the base plate 10 and having a plurality of layers (six layers) of the metal meshes 21, in which the metal wires 22 forming the metal meshes 21 have the flat portions 23, the area of contact with the refrigerant in the liquid phase (the primary refrigerant 201 in the cooling device 210) in which the heating source 100 is immersed increases in the metal mesh stacked member 20, so that the heat radiation area of the metal mesh stacked member 20 increases, and many fine pore portions, which are advantageous in generating air bubbles composed of the refrigerant in a gas phase (the primary refrigerant 201 in the cooling device 210), are present in the metal mesh stacked member 20, so that the amount of generation of the air bubbles increases. Accordingly, also in the evaporation unit structure 2, it is possible to promote a phase change from a liquid phase to a gas phase of the refrigerant in the liquid phase (the primary refrigerant 201 in the cooling device 210) in which the heating source 100, which is a cooling target, is immersed, and as a result, the cooling characteristics for the heating source 100 immersed in the refrigerant in the liquid phase (the primary refrigerant 201 in the cooling device 210) are improved.

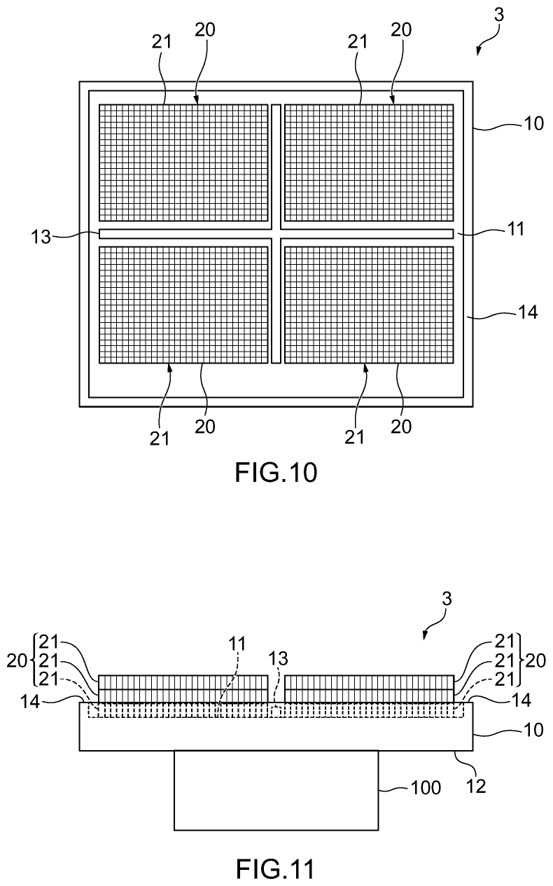

Next, an evaporation unit structure according to a third embodiment example of the present disclosure will be described using the accompanying drawings. Since the evaporation unit structure according to the third embodiment example has main components in common with the evaporation unit structures according to the first and second embodiment examples, same components as the components of the evaporation unit structures of the first and second embodiment examples are described by using the same reference signs. Note that FIG. 10 is a plan view explaining an outline of the evaporation unit structure according to the third embodiment example of the present disclosure. FIG. 11 is a side view explaining the outline of the evaporation unit structure according to the third embodiment example of the present disclosure.

In the evaporation unit structure 1 according to the first embodiment example, the single metal mesh stacked member 20 is provided along the extending direction of the first surface 11 of the base plate 10, but instead of this, in an evaporation unit structure 3 according to the third embodiment example, a plurality of the metal mesh stacked members 20 are provided along the extending direction of the first surface 11 of the base plate 10 as illustrated in FIGS. 10 and 11. As described, an installation number of the metal mesh stacked members 20 is properly selectable according to use conditions or the like of the evaporation unit structure of the present disclosure.

In the evaporation unit structure 3, four of the metal mesh stacked members 20 are provided on the first surface 11 of the base plate 10 at predetermined intervals. As to the plurality of metal mesh stacked members 20, 20, 20, . . . , the stack number of the metal meshes 21 in the respective metal mesh stacked members 20 may be the same or may be different. In the evaporation unit structure 3, as to the plurality of metal mesh stacked members 20, 20, 20, . . . , the stack number of the metal meshes 21 in the respective metal mesh stacked members 20 is all the same for ease of description.

In the evaporation unit structure 3, a positioning portion 13 for positioning the plurality of metal mesh stacked members 20, 20, 20, . . . on the first surface 11 of the base plate 10 is provided on the first surface 11 of the base plate 10. The positioning portion 13 extends along a boundary portion formed among the plurality of metal mesh stacked members 20, 20, 20, . . . . As an aspect of the positioning portion 13, a projecting portion formed on the first surface 11 of the base plate 10 and protruding in the thickness direction (the Z-direction) of the base plate 10, for example, is cited. Since the positioning portion 13 is provided on the first surface 11 of the base plate 10, it is possible to prevent the plurality of metal mesh stacked members 20, 20, 20, . . . from being overlapped on one another on the first surface 11 of the base plate 10. Note that the positioning portion 13 is a site provided according to necessity, and an aspect in which the positioning portion 13 is not provided may be adopted.

Further, in the evaporation unit structure 3, a projection 14 protruding in the thickness direction (the Z-direction) of the base plate 10 is provided on a peripheral edge portion on the first surface 11 of the base plate 10. In the evaporation unit structure 3, the projection 14 is provided throughout the entire peripheral edge portion of the base plate 10. Since the projection 14 is provided on the peripheral edge portion on the first surface 11 of the base plate 10, it is possible to prevent a bonding member such as solder from entering the metal mesh stacked members 20 along the base plate 10 when the evaporation unit structure 3 is thermally connected to the heating source 100. That is, the projection 14 functions as a bonding member entry preventing portion for the metal mesh stacked members 20. Note that the projection 14 is a site provided according to necessity, and an aspect in which the projection 14 is not provided may be adopted.

Also in the aspect of the evaporation unit structure 3 in which the plurality of metal mesh stacked members 20, 20, 20, . . . are provided, because of including the base plate 10 having the first surface 11 and the second surface 12, the heating source 100 immersed in the refrigerant in a liquid phase (for example, the primary refrigerant 201 in the cooling device 210) being thermally connected to the second surface 12, and the plurality of metal mesh stacked members 20 thermally connected to the first surface 11 of the base plate 10 and having a plurality of layers of the metal meshes 21, in which the metal wires 22 forming the metal meshes 21 have the flat portions 23, the area of contact with the refrigerant in the liquid phase (the primary refrigerant 201 in the cooling device 210) in which the heating source 100 is immersed increases in the metal mesh stacked members 20, so that the heat radiation area of the metal mesh stacked members 20 increases, and many fine pore portions, which are advantageous in generating air bubbles composed of the refrigerant in a gas phase (the primary refrigerant 201 in the cooling device 210), are present in the metal mesh stacked members 20, so that the amount of generation of the air bubbles increases. Accordingly, also in the evaporation unit structure 3, it is possible to promote a phase change from a liquid phase to a gas phase of the refrigerant in the liquid phase (the primary refrigerant 201 in the cooling device 210) in which the heating source 100, which is a cooling target, is immersed, and as a result, the cooling characteristics for the heating source 100 immersed in the refrigerant in the liquid phase (the primary refrigerant 201 in the cooling device 210) are improved.

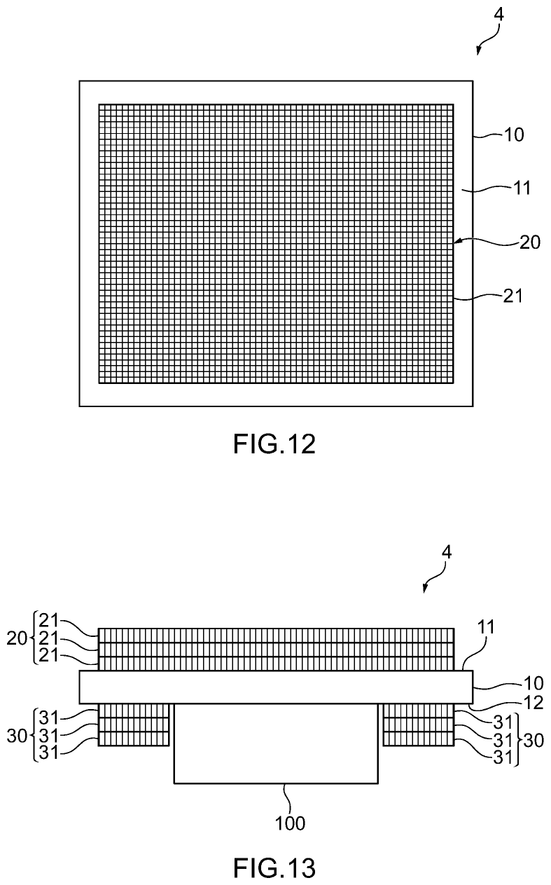

Next, an evaporation unit structure according to a fourth embodiment example of the present disclosure will be described using the accompanying drawings. Since the evaporation unit structure according to the fourth embodiment example has main components in common with the evaporation unit structures according to the first to third embodiment examples, same components as the components of the evaporation unit structures according to the first to third embodiment examples are described by using the same reference signs. Note that FIG. 12 is a plan view explaining an outline of the evaporation unit structure according to the fourth embodiment example of the present disclosure. FIG. 13 is a side view explaining the outline of the evaporation unit structure according to the fourth embodiment example of the present disclosure.

In the evaporation unit structures 1, 2, and 3 according to the first to third embodiment examples, the metal mesh stacked member 20 is provided on the first surface 11 of the base plate 10, and the metal mesh stacked member 20 is not provided on the second surface 12 of the base plate 10, but instead of this, in an evaporation unit structure 4 according to the fourth embodiment example, not only is the metal mesh stacked member 20 provided on the first surface 11 of the base plate 10, but also metal mesh stacked members, that is, other metal mesh stacked members 30, are provided on the second surface 12 of the base plate 10 as illustrated in FIGS. 12 and 13.

From the foregoing, in the evaporation unit structure 4, the metal mesh stacked member 20 is thermally connected to the first surface 11 of the base plate 10 to which the heating source 100 is not thermally connected, and the other metal mesh stacked members 30 are thermally connected to the second surface 12 of the base plate 10 to which the heating source 100 is thermally connected. As described, an installation position of the metal mesh stacked member 20 on the base plate 10 is not particularly limited and is properly selectable according to use conditions or the like of the evaporation unit structure of the present disclosure.

In the evaporation unit structure 4, the single metal mesh stacked member 20 is provided on the first surface 11 of the base plate 10, and a plurality of other metal mesh stacked members 30 are provided on the second surface 12 of the base plate 10 at a predetermined interval. In the evaporation unit structure 4, the other metal mesh stacked members 30 are provided on both sides of the heating source 100. Further, the evaporation unit structure 4 is in an aspect in which the area in a plan view of the other metal mesh stacked members 30 is smaller than the area in a plan view of the metal mesh stacked member 20.

The other metal mesh stacked members 30 have a structure similar to that of the metal mesh stacked member 20. That is, the other metal mesh stacked members 30 have a stacked structure in which a plurality of metal meshes 31, 31, 31, . . . are stacked in the thickness direction of the base plate 10. Further, the other metal mesh stacked members 30 have a structure in which the plurality of metal meshes 31, 31, 31, . . . are stacked in the thickness direction of the metal meshes 31. Further, metal wires forming the metal meshes 31 have flat portions.

A stack number of the metal meshes 31 of the other metal mesh stacked members 30 is not particularly limited so long as there are a plurality of layers which are two or more layers, and the other metal mesh stacked members 30 of the evaporation unit structure 4 have a stacked structure composed of three layers of the metal meshes 31 like the metal mesh stacked member 20. Note that the stack number of the metal meshes 31 of the other metal mesh stacked members 30 may be different from the stack number of the metal meshes 21 of the metal mesh stacked member 20.

Note that the other metal mesh stacked members 30 are also formed with the plurality of metal meshes 31, 31, 31, . . . stacked. That is, the plurality of metal meshes 31, 31, 31, . . . which are separate elements are pressure-welded in the stacked state, so that the plurality of metal meshes 31, 31, 31, . . . are closely stacked.

Also in the aspect of the evaporation unit structure 4 in which the metal mesh stacked member 20 is provided on the first surface 11 of the base plate 10 and in which the other metal mesh stacked members 30 are provided on the second surface 12 of the base plate 10, because of including the base plate 10 having the first surface 11 and the second surface 12, the heating source 100 immersed in the refrigerant in a liquid phase (for example, the primary refrigerant 201 in the cooling device 210) being thermally connected to the second surface 12, the metal mesh stacked member 20 thermally connected to the first surface 11 of the base plate 10 and having a plurality of layers of the metal meshes 21, and the other metal mesh stacked members 30 thermally connected to the second surface 12 of the base plate 10 and having a plurality of layers of the metal meshes 31, in which the metal wires 22 forming the metal meshes 21, 31 have the flat portions 23, the area of contact with the refrigerant in the liquid phase (the primary refrigerant 201 in the cooling device 210) in which the heating source 100 is immersed increases in the metal mesh stacked member 20 and the other metal mesh stacked members 30, so that the heat radiation area of the metal mesh stacked members increases, and many fine pore portions, which are advantageous in generating air bubbles composed of the refrigerant in a gas phase (the primary refrigerant 201 in the cooling device 210), are present in the metal mesh stacked members, so that the amount of generation of the air bubbles increases. Accordingly, also in the evaporation unit structure 4, it is possible to promote a phase change from a liquid phase to a gas phase of the refrigerant in the liquid phase (the primary refrigerant 201 in the cooling device 210) in which the heating source 100, which is a cooling target, is immersed, and as a result, the cooling characteristics for the heating source 100 immersed in the refrigerant in the liquid phase (the primary refrigerant 201 in the cooling device 210) are improved.

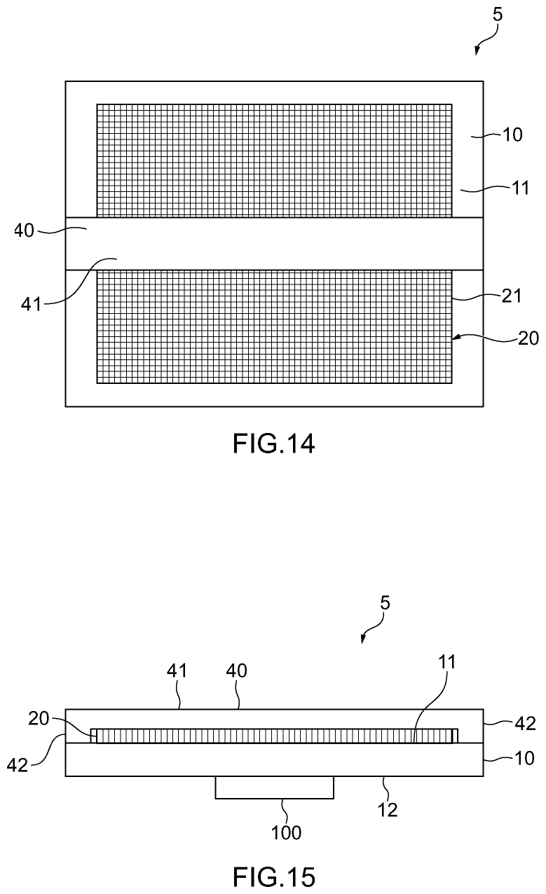

Next, an evaporation unit structure according to a fifth embodiment example of the present disclosure will be described using the accompanying drawings. Since the evaporation unit structure according to the fifth embodiment example has main components in common with the evaporation unit structures according to the first to fourth embodiment examples, same components as the components of the evaporation unit structures according to the first to fourth embodiment examples are described by using the same reference signs. Note that FIG. 14 is a plan view explaining an outline of the evaporation unit structure according to the fifth embodiment example of the present disclosure. FIG. 15 is a side view explaining the outline of the evaporation unit structure according to the fifth embodiment example of the present disclosure.

As illustrated in FIGS. 14 and 15, an evaporation unit structure 5 according to the fifth embodiment example is in an aspect in which a support member 40 for preventing the metal mesh stacked member 20 from falling out of the base plate 10 is further provided for the evaporation unit structure 1 according to the first embodiment example. That is, the support member 40 functions as a metal mesh stacked member falling-out preventing part that prevents the metal mesh stacked member 20 from falling out of the first surface 11 of the base plate 10. The support member 40 has a planar supporting portion 41 which covers a partial region of a surface of the metal mesh stacked member 20 and which is in contact with the partial region of the surface of the metal mesh stacked member 20, and leg portions 42 for fixing the supporting portion 41 to the first surface 11 of the base plate 10, the leg portions 42 being provided on both end portions of the supporting portion 41. The leg portions 42 are fixed to a peripheral edge portion of the first surface 11 of the base plate 10, the peripheral edge portion being a region in which the metal mesh stacked member 20 is not thermally connected to the first surface 11 of the base plate 10.

Since the support member 40 is fixed to the first surface 11 of the base plate 10 and since the supporting portion 41 of the support member 40 is in contact (surface contact) with the surface of the metal mesh stacked member 20, the support member 40 prevents the metal mesh stacked member 20 from falling out of the base plate 10. In the evaporation unit structure 5, the supporting portion 41 of the support member 40 covers a partial region in the width direction of the metal mesh stacked member 20.

The support member 40 is not particularly limited in material, and metals such as copper, a copper alloy, aluminum, an aluminum alloy, stainless steel, nickel, a nickel alloy, titanium, and a titanium alloy, for example, can be cited.

Also in the aspect of the evaporation unit structure 5 in which the support member 40 is further provided, because of including the base plate 10 having the first surface 11 and the second surface 12, the heating source 100 immersed in the refrigerant in a liquid phase (for example, the primary refrigerant 201 in the cooling device 210) being thermally connected to the second surface 12, and the plurality of metal mesh stacked members 20 thermally connected to the first surface 11 of the base plate 10 and having a plurality of layers of the metal meshes 21, in which the metal wires 22 forming the metal meshes 21 have the flat portions 23, the area of contact with the refrigerant in the liquid phase (the primary refrigerant 201 in the cooling device 210) in which the heating source 100 is immersed increases in the metal mesh stacked members 20, so that the heat radiation area of the metal mesh stacked members 20 increases, and many fine pore portions, which are advantageous in generating air bubbles composed of the refrigerant in a gas phase (the primary refrigerant 201 in the cooling device 210), are present in the metal mesh stacked members 20, so that the amount of generation of the air bubbles increases. Accordingly, also in the evaporation unit structure 5, it is possible to promote a phase change from a liquid phase to a gas phase of the refrigerant in the liquid phase (the primary refrigerant 201 in the cooling device 210) in which the heating source 100, which is a cooling target, is immersed, and as a result, the cooling characteristics for the heating source 100 immersed in the refrigerant in the liquid phase (the primary refrigerant 201 in the cooling device 210) are improved.

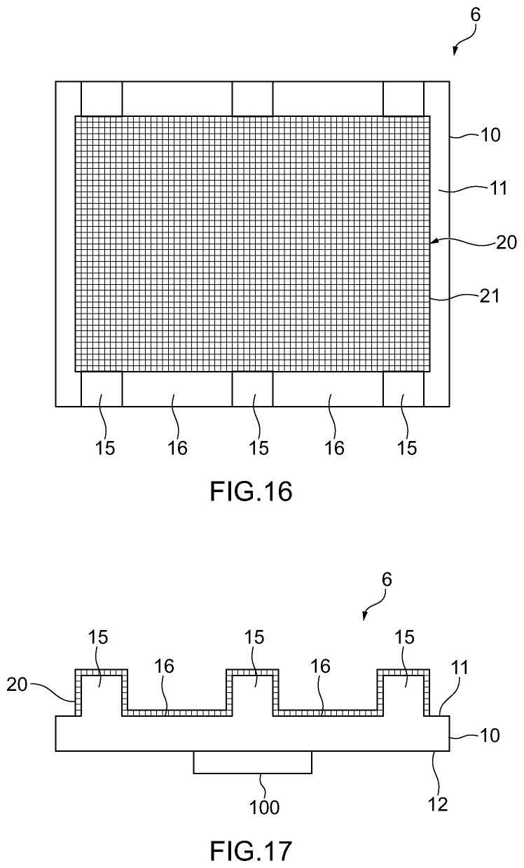

Next, an evaporation unit structure according to a sixth embodiment example of the present disclosure will be described using the accompanying drawings. Since the evaporation unit structure according to the sixth embodiment example has main components in common with the evaporation unit structures according to the first to fifth embodiment examples, same components as the components of the evaporation unit structures according to the first to fifth embodiment examples are described by using the same reference signs. Note that FIG. 16 is a plan view explaining an outline of the evaporation unit structure according to the sixth embodiment example of the present disclosure. FIG. 17 is a side view explaining the outline of the evaporation unit structure according to the sixth embodiment example of the present disclosure.

In the evaporation unit structures 1, 2, 3, 4, and 5 according to the first to fifth embodiment examples, the first surface 11 of the base plate 10 is a flat surface, but instead of this, in an evaporation unit structure 6 according to the sixth embodiment example, the first surface 11 of the base plate 10 has protruding portions 15 protruding in the thickness direction (the Z-direction) of the base plate 10 as illustrated in FIGS. 16 and 17. Accordingly, in the evaporation unit structure 6, the first surface 11 of the base plate 10 is a recessed and protruding surface having flat surface portions 16 and the protruding portions 15. From the foregoing, the evaporation unit structure 6 is in an aspect in which the first surface 11 of the base plate 10 has a surface area increased from the surface area of the first surface 11 of the base plate 10 of the evaporation unit structures 1, 2, 3, 4, and 5.

In the evaporation unit structure 6, the metal mesh stacked member 20 is thermally connected to the flat surface portions 16. Further, in the evaporation unit structure 6, the metal mesh stacked member 20 is thermally connected to the protruding portions 15. Specifically, the metal mesh stacked member 20 is thermally connected to a surface of top portions and a surface of side portions of the protruding portions 15.

In the evaporation unit structure 6, since not only is the metal mesh stacked member 20 thermally connected to the flat surface portions 16, but also the metal mesh stacked member 20 is thermally connected to the protruding portions 15, the surface area of the metal mesh stacked member 20 increases. Accordingly, in the evaporation unit structure 6, the area of contact between the refrigerant in the liquid phase (the primary refrigerant 201 in the cooling device 210) in which the heating source 100 is immersed and the metal mesh stacked member 20 further increases, so that the heat radiation area of the metal mesh stacked member 20 further increases, and as a result, the cooling characteristics for the heating source 100 immersed in the refrigerant in the liquid phase (the primary refrigerant 201 in the cooling device 210) are further improved.

Next, another embodiment example of the evaporation unit structure of the present disclosure will be described. In the evaporation unit structures according to the first to third embodiment examples and the evaporation unit structures according to the fifth to sixth embodiment examples, the metal mesh stacked member is thermally connected to the first surface of the base plate, and in the evaporation unit structure according to the fourth embodiment example, the metal mesh stacked members are thermally connected to the first surface and the second surface of the base plate, but instead of this, an aspect may be adopted in which the metal mesh stacked member is thermally connected to the second surface of the base plate and in which the metal mesh stacked member is not thermally connected to the first surface of the base plate. Further, in the evaporation unit structure according to the fourth embodiment example, the plurality of other metal mesh stacked members are provided on the second surface of the base plate, but instead of this, an aspect may be adopted in which another single metal mesh stacked member is provided on the second surface of the base plate.

In the evaporation unit structures according to the above-described respective embodiment examples, the base block has a rectangular shape in a plan view, but instead of this, may have a triangular shape, a pentagonal or higher-order polygonal shape, a circular shape, a shape having a linear portion and a curved portion, or the like. Further, in the evaporation unit structures according to the above-described respective embodiment examples, the metal mesh stacked member has a rectangular shape in a plan view, but instead of this, may have a triangular shape, a pentagonal or higher-order polygonal shape, a circular shape, a shape having a linear portion and a curved portion, or the like.

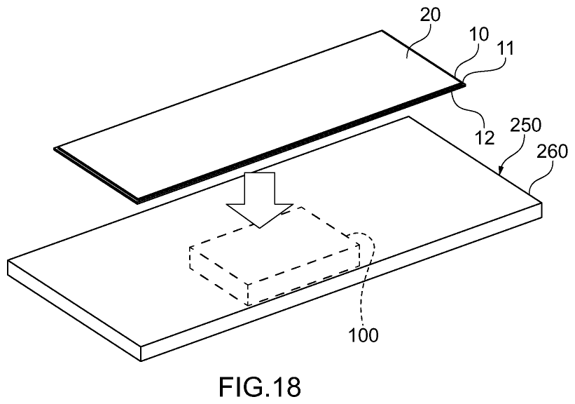

Next, another usage example of the evaporation unit structure of the present disclosure will be described. Note that FIG. 18 is an explanatory view illustrating another usage of the evaporation unit structure according to the first embodiment example of the present disclosure.

As illustrated in FIG. 18, in the evaporation unit structure of the present disclosure (in FIG. 18, the evaporation unit structure 1 according to the first embodiment example), a vapor chamber 250 that is a heat transport member may be thermally connected to the second surface 12 of the base plate 10 instead of the heating source 100.

The vapor chamber 250 is a planar heat pipe. The vapor chamber 250 specifically includes a container 260 in which a cavity portion is formed inside by overlapping two facing plate-like bodies, that is, one plate-like body and another plate-like body facing the one plate-like body, a working fluid enclosed in the cavity portion, and a vapor flow path which is provided in the cavity portion and through which the working fluid in a gas phase flows. The cavity portion is a sealed space and is decompressed by degassing.

A usage is cited in which the vapor chamber 250 thermally connected to the heating source 100 is immersed in a refrigerant in a liquid phase (for example, the primary refrigerant 201 in the cooling device 210) together with the heating source 100 and in which the evaporation unit structure (the evaporation unit structure 1) of the present disclosure in the state immersed in the refrigerant in the liquid phase is thermally connected to the vapor chamber 250 immersed in this refrigerant in the liquid phase.

Since the evaporation unit structure (the evaporation unit structure 1) of the present disclosure can promote a phase change from a liquid phase to a gas phase of the refrigerant in which the heating source 100, which is a cooling target, and the vapor chamber 250 thermally connected to the heating source 100 are immersed, heat transport characteristics of the vapor chamber 250 immersed in the refrigerant in the liquid phase are improved, and as a result, the cooling characteristics for the heating source 100 are improved.

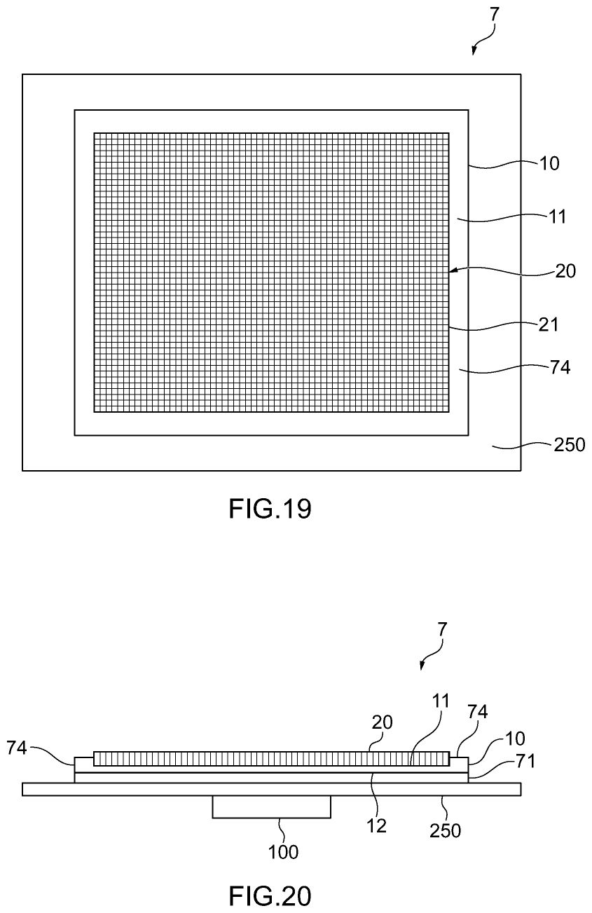

Next, another usage example in another embodiment example of the evaporation unit structure of the present disclosure will be described. Note that FIG. 19 is a plan view explaining an outline of the other usage in the other embodiment example of the evaporation unit structure of the present disclosure. FIG. 20 is a side view explaining the outline of the other usage in the other embodiment example of the evaporation unit structure of the present disclosure.

First, the other embodiment example of the evaporation unit structure of the present disclosure will be described. As illustrated in FIGS. 19 and 20, in an evaporation unit structure 7 according to the other embodiment example of the present disclosure, the evaporation unit structure 1 according to the first embodiment example is further provided with a projection 74 on the peripheral edge portion on the first surface 11 of the base plate 10.

In the evaporation unit structure 7, the projection 74 protruding in the thickness direction (the Z-direction) of the base plate 10 is provided throughout the entire peripheral edge portion of the base plate 10. Since the projection 74 is provided on the peripheral edge portion on the first surface 11 of the base plate 10, it is possible to prevent a bonding member 71 such as solder from entering the metal mesh stacked member 20 along the base plate 10 when the evaporation unit structure 7 is thermally connected to the heating source 100. That is, the projection 74 functions as a bonding member entry preventing portion for the metal mesh stacked member 20.

As illustrated in FIGS. 19 and 20, in the evaporation unit structure 7, as another usage of the evaporation unit structure, the vapor chamber 250, which is the heat transport member, is thermally connected to the second surface 12 of the base plate 10 instead of the heating source 100. The vapor chamber 250 is thermally connected to the heating source 100. The vapor chamber 250 thermally connected to the heating source 100 is thermally connected to the second surface 12 of the base plate 10 with the bonding member 71 such as solder.

Note that in FIGS. 19 and 20, in the evaporation unit structure 7, the vapor chamber 250 is thermally connected to the base plate 10 with the bonding member 71 such as solder for ease of description, but instead of the vapor chamber 250, a heat conductive plate such as a metal plate or another structure may be thermally connected to the base plate 10.

The vapor chamber 250 thermally connected to the heating source 100 is immersed in the refrigerant in a liquid phase (for example, the primary refrigerant 201 in the cooling device 210) together with the heating source 100, and as another usage of the evaporation unit structure, a usage is cited in which the evaporation unit structure 7 in the state immersed in the refrigerant in the liquid phase is thermally connected to the vapor chamber 250 immersed in this refrigerant in the liquid phase.

Since the evaporation unit structure 7 can promote a phase change from a liquid phase to a gas phase of the refrigerant in which the heating source 100, which is a cooling target, and the vapor chamber 250 thermally connected to the heating source 100 are immersed, the heat transport characteristics of the vapor chamber 250 immersed in the refrigerant in the liquid phase are improved, and as a result, the cooling characteristics for the heating source 100 are improved.

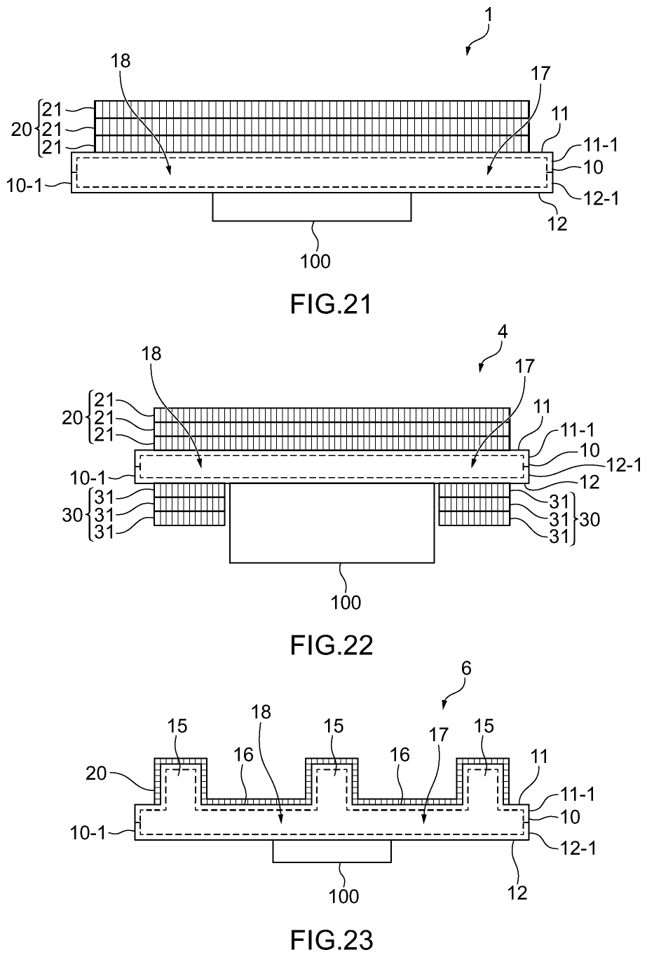

In the first embodiment example, the base plate 10 is a solid plate-like member, but the base plate may be a hollow plate-like member and may function as a vapor chamber. An example of such a base plate is illustrated in FIG. 21. The base plate 10 illustrated in FIG. 21 includes a container 10-1 in which a cavity portion 17 is formed inside by overlapping two facing plate-like bodies, that is, one plate-like body 11-1 forming the first surface 11 and another plate-like body 12-1 forming the second surface 12 and being facing the one plate-like body 11-1, a working fluid (not illustrated) enclosed in the cavity portion 17, and a vapor flow path 18 which is provided in the cavity portion 17 and through which the working fluid in a gas phase flows. Such a base plate 10 functions as a vapor chamber that is a planar heat pipe by means of the container 10-1 in which the cavity portion 17 is formed inside, the working fluid, and the vapor flow path 18. At this time, the container 10-1 is a thin plate-like container, and the cavity portion 17 that is a sealed space is decompressed by degassing.

In the case in which the base plate 10 is a vapor chamber as described, the function of diffusing heat can be improved. Note that the plate-like bodies 11-1, 12-1 forming such a hollow base plate should only be formed by copper, aluminum, stainless steel, titanium, their alloys, or the like, for example, and a capillary structure formed of a mesh, sintered metal, or the like is provided on their inner surfaces (a portion indicated by a broken line in the drawing).

Further, also in the second to sixth embodiment examples, the base plate that functions as a vapor chamber as described above can be employed. As illustrated in FIG. 22, for example, the base plate 10 in the fourth embodiment example may be changed to a vapor chamber. In the example illustrated in FIG. 22, similarly to the example illustrated in FIG. 21, the base plate 10 as the vapor chamber includes the container 10-1 in which the cavity portion 17 is formed inside by overlapping two facing plate-like bodies (the one plate-like body 11-1 and the other plate-like body 12-1), a working fluid (not illustrated) enclosed in the cavity portion 17, and the vapor flow path 18 which is provided in the cavity portion 17 and through which the working fluid in a gas phase flows.

Further, as illustrated in FIG. 23, the base plate 10 in the sixth embodiment example may be changed to a vapor chamber. In the example illustrated in FIG. 23, similarly to the examples illustrated in FIGS. 21 and 22, the base plate 10 as the vapor chamber includes the container 10-1 in which the cavity portion 17 is formed inside by overlapping two facing plate-like bodies (the one plate-like body 11-1 and the other plate-like body 12-1), a working fluid (not illustrated) enclosed in the cavity portion 17, and the vapor flow path 18 which is provided in the cavity portion 17 and through which the working fluid in a gas phase flows. At this time, the cavity portion 17 is formed even in the inside of the protruding portions 15, and the inside of the protruding portions 15 and the inside of the flat surface portions 16 communicate with one another.

By improving heat conductivity of the base plate, performance of the evaporation unit structure can be improved. The example in which the base plate of each of the embodiment examples is changed to the vapor chamber has been described above, but heat conductivity of the base plate may be improved by adopting another configuration for the base plate. For example, in order to improve heat conductivity of the base plate, a heat pipe may be laid out in the base plate, or another member such as a graphite sheet or a cladding material may be combined with the base plate.

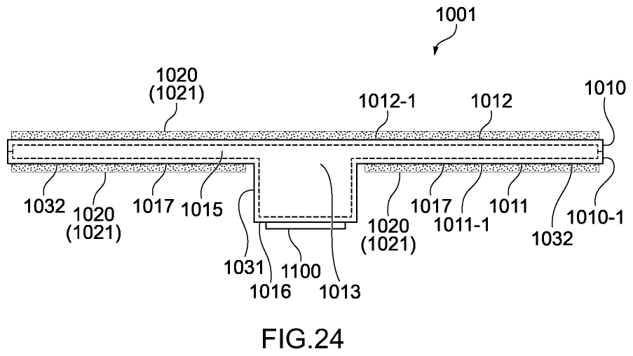

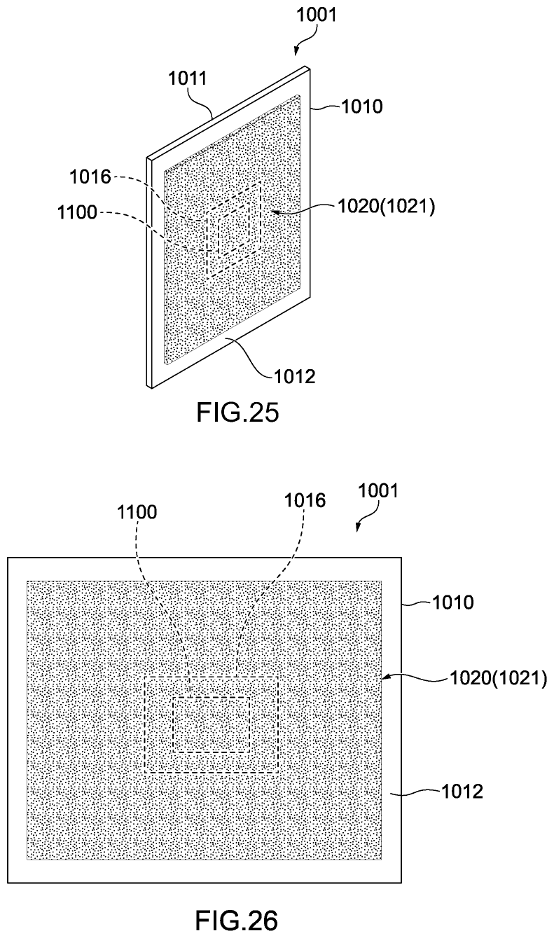

Hereinafter, an evaporation unit structure according to a seventh embodiment example of the present disclosure will be described using the accompanying drawings. Note that FIG. 24 is a side view explaining an outline of the evaporation unit structure according to the seventh embodiment example of the present disclosure. FIG. 25 is a perspective view explaining the outline of the evaporation unit structure according to the seventh embodiment example of the present disclosure. FIG. 26 is a plan view explaining the outline of the evaporation unit structure according to the seventh embodiment example of the present disclosure.

As illustrated in FIGS. 24, 25, and 26, the evaporation unit structure 1 according to the seventh embodiment example of the present disclosure includes a vapor chamber 1010 having a first surface 1011 and a second surface 1012 as well as a boiling promoting part 1020 which is provided on the first surface 1011 and/or the second surface 1012 of the vapor chamber 1010, which contacts a refrigerant in a liquid phase (not illustrated in FIGS. 24 to 26), and which is formed of a metal material. A heating source 1100 immersed in the refrigerant in the liquid phase is thermally connected to the first surface 1011 of the vapor chamber 1010. In the evaporation unit structure 1001, the boiling promoting part 1020 is provided on the first surface 1011 and the second surface 1012 of the vapor chamber 1010. That is, in the evaporation unit structure 1001, the boiling promoting part 1020 is thermally connected to the first surface 1011 and the second surface 1012 of the vapor chamber 1010.

In the vapor chamber 1010 of the evaporation unit structure 1001, the first surface 1011 is opposite the second surface 1012, and the boiling promoting part 1020 is thermally connected to the second surface 1012. From the foregoing, the boiling promoting part 1020 provided on the second surface 1012 is arranged opposite the heating source 1100 with the vapor chamber 1010 interposed therebetween. Further, in the evaporation unit structure 1001, the boiling promoting part 1020 is also provided on the first surface 1011 of the vapor chamber 1010. Accordingly, the boiling promoting part 1020 is also thermally connected to the first surface 1011 of the vapor chamber 1010.

The vapor chamber 1010 includes the container 1010-1 in which a cavity portion 1013 is formed inside by overlapping two facing plate-like bodies, that is, one plate-like body 1011-1 forming the first surface 1011 and another plate-like body 1012-1 forming the second surface 1012 and being facing the one plate-like body 1011-1, a working fluid (not illustrated) enclosed in the cavity portion 1013, and a vapor flow path 1015 which is provided in the cavity portion 1013 and through which the working fluid in a gas phase flows. A vapor chamber 1010 that is a planar heat pipe is formed by the container 1010-1 in which the cavity portion 1013 is formed inside, the working fluid, and the vapor flow path 1015. The container 1010-1 is a thin plate-like container.

The first surface 1011 has a flat planar site 1032 and a protruding site 1031 protruding outwardly from the planar site 1032. In the vapor chamber 1010, the single protruding site 1031 is provided at the center of the first surface 1011. Further, a side surface of the protruding site 1031 protrudes from the planar site 1032 in the vertical direction. On the other hand, the second surface 1012 does not have a protruding site, but the entire second surface 1012 is a flat planar site. Since the first surface 1011 has the planar site 1032 and the protruding site 1031 protruding outwardly from the planar site 1032, the container 1010-1 has a flat surface portion 1017 and a protruding portion 1016 protruding outwardly from the flat surface portion 1017. Accordingly, in the vapor chamber 1010, the single protruding portion 1016 is provided at the center of the first surface 1011, and a protruding portion is not provided on the second surface 1012. From the foregoing, the flat surface portion 1017 and the protruding portion 1016 of the container 1010-1 are molded integrally. Further, a side surface of the protruding portion 1016 protrudes from the flat surface portion 1017 in the vertical direction.

The cavity portion 1013 is a sealed space and is decompressed by degassing. An internal space of the protruding portion 1016 of the container 1010-1 communicates with an internal space of the flat surface portion 1017, and the cavity portion 1013 of the container 1010-1 is formed by the internal space of the protruding portion 1016 and the internal space of the flat surface portion 1017. Accordingly, the working fluid can flow between the internal space of the protruding portion 1016 and the internal space of the flat surface portion 1017.

The container 1010-1 is not particularly limited in shape, but in the vapor chamber 1010, a polygonal shape such as a quadrangular shape, a circular shape, an elliptical shape, a shape having a straight line portion and a bending portion, and the like in a plan view (a state in which the flat surface portion 1017 of the container 1010-1 is viewed from the vertical direction), for example, are cited.

The protruding portion 1016 provided on the first surface 1011 of the container 1010-1 is a site to which the heating source 1100 that is an element to be cooled is thermally connected, and functions as a heat receiving portion of the vapor chamber 1010. The heating source 1100 is thermally connected to a tip end of the protruding portion 1016. From the foregoing, the protruding portion 1016 has the heat receiving portion to which the heating source 1100 is thermally connected, and the boiling promoting part 1020 is not provided at the tip end of the protruding portion 1016 to which the heating source 1100 is thermally connected. As the heating source 1100, an electronic component such as a central processing unit mounted on a wiring board (not illustrated), for example is cited.

On the other hand, the boiling promoting part 1020 is provided substantially throughout the entire outer surface of the flat surface portion 1017 provided on the first surface 1011 of the container 1010-1, and the boiling promoting part 1020 is thermally connected to the first surface 1011 of the vapor chamber 1010.

The second surface 1012 of the vapor chamber 1010 is not provided with a protruding site but is a flat surface as a whole. The boiling promoting part 1020 is provided substantially throughout the entire outer surface of the second surface 1012, and the boiling promoting part 1020 is thermally connected to the second surface 1012 of the vapor chamber 1010.

The cavity portion 1013 of the container 1010-1 is provided with a wick structure (not illustrated) that generates a capillary force. The wick structure is provided throughout the entire container 1010-1, for example. By the capillary force of the wick structure, the working fluid changed in phase from a gas phase to a liquid phase in a site (heat radiation portion) other than the heat receiving portion of the vapor chamber 1010 returns to the heat receiving portion from the heat radiation unit of the vapor chamber 1010. As the wick structure, although not particularly limited, a sintered body of metal powder such as copper powder, a metal mesh formed of metal wires, non-woven fabric, grooves (a plurality of narrow slits) formed in an inner surface of the container 1010-1, and the like, or their combinations, for example, can be cited.

Further, in the protruding portion 1016, a first wick structure having a large capillary force is provided as a wick structure at a heat receiving site to which the heating source 1100 is to be connected, that is, on a bottom portion of the protruding portion 1016, so that dry-out of the vapor chamber 1010 can be prevented. On the other hand, a second wick structure having a capillary force smaller than that of the first wick structure is provided as a wick structure in a site other than the bottom portion of the protruding portion 1016, for example, on a side surface of the protruding portion 1016 of the container 1010-1, the flat surface portion 1017 of the container 1010-1, and a side surface of the container 1010-1, so that flow path resistance when the working fluid in a liquid phase returns can be reduced.

The vapor flow path 1015 is an internal space of the container 1010-1 and extends throughout the entire container 1010-1. Accordingly, the working fluid in a gas phase can flow throughout the entire container 1010-1 because of the vapor flow path 1015. Further, a pillar (prism-shaped member) for maintaining the internal space of the container 1010-1 can be provided in the vapor flow path 1015 according to necessity. As the pillar, although not particularly limited, a pillar of a composite material in which a circumference of a metal member (for example, a copper member) having a prism shape is covered by a wick structure, a sintered body of metal powder such as copper powder having a prism shape, and the like, for example, can be cited in order to reduce flow path resistance when the working fluid in the liquid phase returns.

As a material of the container 1010-1, stainless steel, copper, a copper alloy, aluminum, an aluminum alloy, tin, a tin alloy, titanium, a titanium alloy, nickel, a nickel alloy, and the like, for example, can be cited.

The working fluid to be enclosed in the cavity portion 1013 is properly selectable according to compatibility with the material of the container 1010-1, and water, fluorocarbons, cyclopentane, ethylene glycol, their mixtures, and the like, for example, can be cited.

The vapor chamber 1010 is a member that diffuses heat of the heating source 1100 thermally connected to the protruding portion 1016 of the first surface 1011 to the entire vapor chamber 1010 by means of the heat transport function of the vapor chamber 1010 and transmits the heat diffused to the entire vapor chamber 1010 to the boiling promoting part 1020.

As illustrated in FIGS. 24, 25, and 26, in the evaporation unit structure 1001 according to the seventh embodiment example of the present disclosure, the boiling promoting part 1020 is a sintered body layer 1021 of metal powder. Since the boiling promoting part 1020 is the sintered body layer 1021 of metal powder, the boiling promoting part 1020 provided on the first surface 1011 and the second surface 1012 of the vapor chamber 1010 has a structure having a plurality of narrow spaces, that is, a structure having roughened portions in which the first surface 1011 and the second surface 1012 are roughened. In the evaporation unit structure 1001, the sintered body layer 1021 of metal powder functions as the plurality of narrow spaces, that is, the roughened portions. The narrow space is such a relatively narrow space that is formed by two or more members and that is to be a starting point of nucleate boiling, and is open to a side where the refrigerant is present, thus enabling entry of the refrigerant.

Note that in the evaporation unit structure 1001, the thickness of the sintered body layer 1021 of metal powder is properly selectable according to use conditions of the evaporation unit structure 1001, properties of the refrigerant in the liquid phase in which the heating source 1100 is to be immersed, and the like. It is preferable that the thickness of the sintered body layer 1021 of metal powder should be 0.2 mm or more from a viewpoint of reliably obtaining fine structures that are advantageous in generating nuclei of boiling to reliably smooth production of nuclei of boiling, for example, although it depends on a heat input condition when the sintered body is formed, and should be 0.8 mm or less from viewpoints of making the generated nuclei of boiling easier to leave the boiling promoting part 1020 and reducing flow path resistance of the refrigerant in the liquid phase to smooth supply of the refrigerant in the liquid phase to a lower portion of the sintered body layer 1021 of metal powder.

Further, an average particle size of the metal powder forming the sintered body layer 1021 of metal powder is properly selectable according to the use conditions of the evaporation unit structure 1001, the properties of the refrigerant in the liquid phase in which the heating source 1100 is to be immersed, and the like. It is preferable that the average particle size of the metal powder forming the sintered body layer 1021 should be 20 μm or more from the viewpoint of reliably obtaining the fine structures, which are advantageous in generating nuclei of boiling, for example, although it depends on the heat input condition when the sintered body is formed, and should be 0.8 μm or less from the viewpoint of reliably obtaining the boiling promoting part 1020 in which a large number of the fine structures, which are advantageous in generating nuclei of boiling, are present. Further, in the sintered body layer 1021 of metal powder, the average particle size of the metal powder is constant regardless of the distance from the vapor chamber 1010.

As a metal type of the metal powder, copper, a copper alloy, aluminum, an aluminum alloy, stainless steel, and the like, for example, can be cited.

Because of being sintered to the outer surface of the container 1010-1 of the vapor chamber 1010, the sintered body layer 1021 of metal powder is integrated with the vapor chamber 1010 and is thermally connected to the outer surface of the vapor chamber 1010.

The sintered body layer 1021 of metal powder is formed by applying paste containing the metal powder to the first surface 1011 and the second surface 1012 of the vapor chamber 1010 and then performing heating treatment at a predetermined temperature, and the formed sintered body layer 1021 of metal powder is sintered to the first surface 1011 and the second surface 1012 of the vapor chamber 1010.

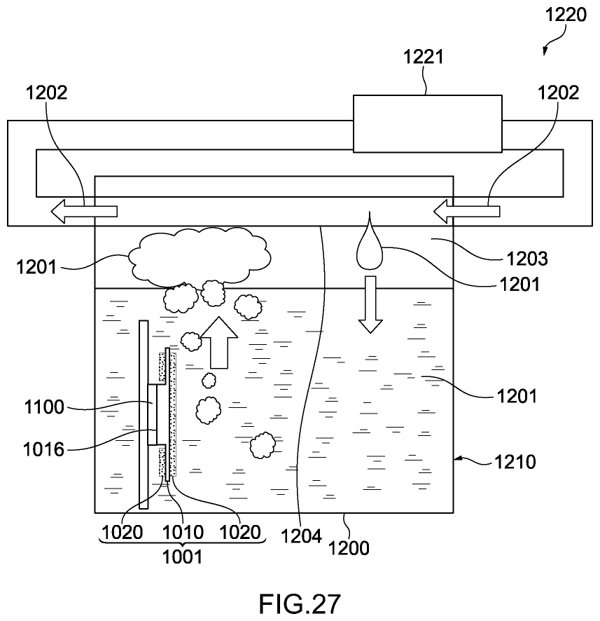

Next, a usage example of the evaporation unit structure 1001 according to the seventh embodiment example of the present disclosure will be described. Note that FIG. 27 is an explanatory view illustrating a usage of the evaporation unit structure according to the seventh embodiment example of the present disclosure.

As illustrated in FIG. 27, the evaporation unit structure 1001 can be used in a cooling system 1220 including a cooling device 1210 having a container 1200 to which the heating source 1100 is thermally connected, a primary refrigerant 1201 in a liquid phase enclosed and retained inside the container 1200, and a condensation tube 1204 which extends through a gas phase portion 1203 inside the container 1200 and through which the secondary refrigerant 1202 in the liquid phase flows, the heating source 1100 being immersed in the primary refrigerant 1201 in the liquid phase enclosed inside the container 1200, and a secondary refrigerant cooling part 1221 to which the condensation tube 1204 extending from the cooling device 1210 is connected, in which the secondary refrigerant 1202 in the liquid phase flowing through the condensation tube 1204 circulates between the cooling device 1210 and the secondary refrigerant cooling part 1221. Specifically, a usage of thermally connecting the evaporation unit structure 1001 according to the seventh embodiment example of the present disclosure in the state immersed in the primary refrigerant 1201 in the liquid phase to the heating source 1100 immersed in the primary refrigerant 1201 in the liquid phase is cited.

In the usage example of the above-described evaporation unit structure 1001, the evaporation unit structure 1001 receives heat from the heating source 1100, and the primary refrigerant 1201 in the liquid phase enclosed and retained inside the container 1200 receives the heat originating from the heating source 1100 from the evaporation unit structure 1001, so that the primary refrigerant 1201 in the liquid phase changes in phase from the liquid phase to a gas phase in a section in contact with the evaporation unit structure 1001. More specifically, the vapor chamber 1010 of the evaporation unit structure 1001 diffuses the heat received from the heating source 1100 throughout the entire vapor chamber 1010 by means of the heat transport function of the vapor chamber 1010, and the heat diffused throughout the entire vapor chamber 1010 is transmitted from the vapor chamber 1010 to the boiling promoting part 1020 (in the evaporation unit structure 1001, the sintered body layer 1021 of metal powder). The heat transmitted to the boiling promoting part 1020 is transmitted from the boiling promoting part 1020 to the primary refrigerant 1201 in the liquid phase in contact with the boiling promoting part 1020. The primary refrigerant 1201 in the liquid phase changes in phase to a gas phase in the section in contact with the boiling promoting part 1020 to cause many air bubbles of the primary refrigerant 1201 to be formed. Since the primary refrigerant 1201 in the liquid phase changes in phase to the gas phase in the section in contact with the boiling promoting part 1020 to cause air bubbles of the primary refrigerant 1201 to be formed, the heating source 1100 immersed in the primary refrigerant 1201 in the liquid phase is cooled.

The air bubbles of the primary refrigerant 1201 generated in the section in contact with the boiling promoting part 1020 move on to the gas phase portion 1203 inside the container 1200 away from the boiling promoting part 1020, and the primary refrigerant 1201 changes in phase from the gas phase to a liquid phase because of the condensation tube 1204, which extends through the gas phase portion 1203 inside the container 1200 and through which the secondary refrigerant 1202 in the liquid phase flows. Latent heat released from the primary refrigerant 1201 at the time of this phase change is transmitted to the secondary refrigerant 1202 in the liquid phase flowing through the condensation tube 1204.

Since the secondary refrigerant 1202 in the liquid phase having received the latent heat from the primary refrigerant 1201 flows through the condensation tube 1204 from the inside to the outside of the cooling device 1210, the latent heat is transported to the outside of the cooling device 1210. The secondary refrigerant 1202 having received the latent heat is cooled in the secondary refrigerant cooling part 1221 provided on the outside of the cooling device 1210. The primary refrigerant 1201 changed in phase from the gas phase to the liquid phase because of the condensation tube 1204, through which the secondary refrigerant 1202 in the liquid phase flows, drops from the condensation tube 1204 to the primary refrigerant 1201 in the liquid phase retained inside the container 1200.

In the aspect of the evaporation unit structure 1001, because of including the vapor chamber 1010 having the first surface 1011 to which the heating source 1100 immersed in the refrigerant in the liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the sintered body layer 1021 of metal powder, a large number of the fine structures, which are advantageous in generating nuclei of boiling made of the refrigerant in a gas phase, are present in the boiling promoting part 1020, which is the sintered body layer 1021 of metal powder, thus smoothing production of nuclei of boiling. Accordingly, in the aspect of the evaporation unit structure 1, it is possible to promote a phase change from a liquid phase to a gas phase of the refrigerant in which the heating source 1100, which is a cooling target, is immersed, and as a result, cooling characteristics for the heating source 1100 immersed in the refrigerant in the liquid phase are improved.

Further, in the aspect of the evaporation unit structure 1001, since the boiling promoting part 1020, which is the sintered body layer 1021 of metal powder, has a plurality of narrow spaces which the refrigerant can enter, the plurality of narrow spaces can reliably function as the fine structures, which are advantageous in generating nuclei of boiling, to further smooth production of nuclei of boiling.

Further, in the aspect of the evaporation unit structure 1001, since the boiling promoting part 1020, which is the sintered body layer 1021 of metal powder, has the roughened portions in which the first surface 1011 and the second surface 1012 are roughened, the roughened portions can reliably function as the fine structures, which are advantageous in generating nuclei of boiling, to further smooth production of nuclei of boiling.

Further, in the aspect of the evaporation unit structure 1001, since the boiling promoting part 1020 is the sintered body layer 1021 of metal powder, the sintered body layer 1021 of metal powder can reliably function as the plurality of narrow spaces, that is, the roughened portions, to further smooth production of nuclei of boiling.

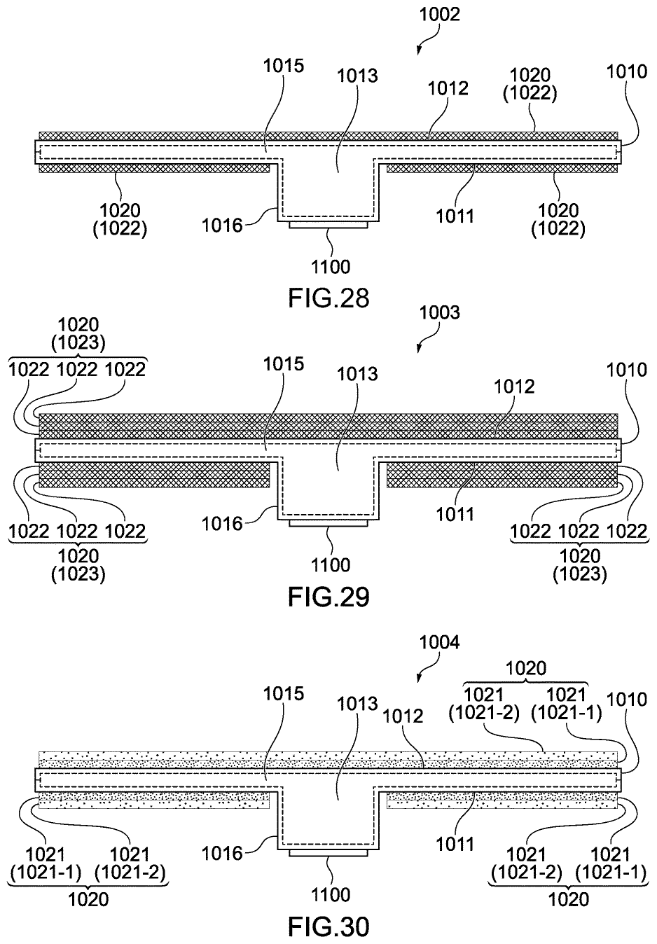

Next, an evaporation unit structure according to an eighth embodiment example of the present disclosure will be described using the accompanying drawings. Since the evaporation unit structure according to the eighth embodiment example has main components in common with the evaporation unit structure according to the seventh embodiment example, same components as the components of the evaporation unit structure according to the seventh embodiment example are described by using the same reference signs. Note that FIG. 28 is a side view explaining an outline of the evaporation unit structure according to the eighth embodiment example of the present disclosure.

In the evaporation unit structure 1001 according to the seventh embodiment example, the boiling promoting part 1020 is the sintered body layer 1021 of metal powder, but instead of this, in an evaporation unit structure 1002 according to the eighth embodiment example, the boiling promoting part 1020 is a metal mesh 1022 as illustrated in FIG. 28. Since the boiling promoting part 1020 is the metal mesh 1022, the boiling promoting part 1020 provided on the first surface 1011 and the second surface 1012 of the vapor chamber 1010 has the structure having a plurality of narrow spaces, that is, the structure having roughened portions in which the first surface 1011 and the second surface 1012 are roughened. In the evaporation unit structure 1002, the metal mesh 1022 functions as the plurality of narrow spaces, that is, the roughened portions.

Further, in the evaporation unit structure 1002, the metal mesh 1022 is a single layer. The metal mesh 1022 has a longitudinal direction and a width direction. The metal mesh 1022 is not particularly limited in shape, but in the evaporation unit structure 1002, is a sheet-like member having a predetermined thickness and has a rectangular shape in a plan view.

The metal mesh 1022 is a screen mesh in which a plurality of first metal wires forming warps and a plurality of second metal wires forming wefts alternately cross up and down. It is preferable that the wire diameter of the metal wires of the metal mesh 1022 should be 20 to 100 μm, for example.

A thickness of the metal mesh 1022 is determined based on a mesh stack number and the wire diameter of the metal wires. In the eighth embodiment example, since the metal mesh 1022 is a single layer, the thickness of the metal mesh 1022 is a thickness depending on the wire diameter of the metal wires.

A mesh number of the metal mesh 1022 is properly selectable according to use conditions of the evaporation unit structure 1002, properties of the refrigerant in a liquid phase in which the heating source 1100 is to be immersed, and the like and is preferably #200 or less from the viewpoint of reliably obtaining the fine structures, which are advantageous in generating nuclei of boiling, for example. On the other hand, it is preferable that the mesh number of the metal mesh 1022 should be #50 or more from the viewpoint of reliably obtaining the boiling promoting part 1020 in which a large number of the fine structures, which are advantageous in generating nuclei of boiling, are present.

In the evaporation unit structure 1002, the metal mesh 1022 is sintered to be integrated with the vapor chamber 1010 and to be thermally connected to the vapor chamber 1010.

The metal mesh 1022 is not particularly limited in material, and copper, a copper alloy, aluminum, an aluminum alloy, nickel, a nickel alloy, stainless steel, titanium, a titanium alloy, and the like, for example, can be cited.

Also in the aspect of the evaporation unit structure 1002, because of including the vapor chamber 1010 having the first surface 1011 to which the heating source 1100 immersed in the refrigerant in a liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the single-layer metal mesh 1022, a large number of the fine structures, which are advantageous in generating nuclei of boiling made of the refrigerant in a gas phase, are present in the boiling promoting part 1020, which is the single-layer metal mesh 1022, thus smoothing production of nuclei of boiling. Accordingly, also in the aspect of the evaporation unit structure 1002, it is possible to promote a phase change from a liquid phase to a gas phase of the refrigerant in which the heating source 1100, which is a cooling target, is immersed, and as a result, the cooling characteristics for the heating source 1100 immersed in the refrigerant in the liquid phase are improved.

Further, in the aspect of the evaporation unit structure 1002, since the boiling promoting part 1020, which is the single-layer metal mesh 1022, has the plurality of narrow spaces, the plurality of narrow spaces can reliably function as the fine structures, which are advantageous in generating nuclei of boiling, to further smooth production of nuclei of boiling.

Further, in the aspect of the evaporation unit structure 1002, since the boiling promoting part 1020, which is the single-layer metal mesh 1022, has the roughened portions in which the first surface 1011 and the second surface 1012 are roughened, the roughened portions can reliably function as the fine structures, which are advantageous in generating nuclei of boiling, to further smooth production of nuclei of boiling.

Further, in the aspect of the evaporation unit structure 1002, since the boiling promoting part 1020 is the metal mesh 1022, the metal mesh 1022 can reliably function as the plurality of narrow spaces, that is, the roughened portions, to further smooth production of nuclei of boiling.

Next, an evaporation unit structure according to a ninth embodiment example of the present disclosure will be described using the accompanying drawings. Since the evaporation unit structure according to the ninth embodiment example has main components in common with the evaporation unit structures according to the seventh and eighth embodiment examples, same components as the components of the evaporation unit structures according to the seventh and eighth embodiment examples are described by using the same reference signs. Note that FIG. 29 is a side view explaining an outline of the evaporation unit structure according to the ninth embodiment example of the present disclosure.

In the evaporation unit structure 1002 according to the eighth embodiment example, the boiling promoting part 1020 is the single-layer metal mesh 1022, but instead of this, in an evaporation unit structure 1003 according to the ninth embodiment example, the boiling promoting part 1020 forms a metal mesh stacked member 1023 in which a metal mesh has a plurality of layers of the metal meshes 1022 as illustrated in FIG. 29. Since the boiling promoting part 1020 is the metal mesh stacked member 1023, the boiling promoting part 1020 provided on the first surface 1011 and the second surface 1012 of the vapor chamber 1010 has the structure having a plurality of narrow spaces, that is, the structure having roughened portions in which the first surface 1011 and the second surface 1012 are roughened. In the evaporation unit structure 1003, the metal mesh stacked member 1023 functions as the plurality of narrow spaces, that is, the roughened portions.

The metal mesh stacked member 1023 has a longitudinal direction and a width direction. The metal mesh stacked member 1023 is not particularly limited in shape, but in the evaporation unit structure 1003, is a sheet-like member having a predetermined thickness and has a rectangular shape in a plan view.

The metal mesh stacked member 1023 has a stacked structure in which the plurality of metal meshes 1022, 1022, 1022, . . . are stacked in the thickness direction of the vapor chamber 1010. Further, the metal mesh stacked member 1023 has a structure in which the plurality of metal meshes 1022, 1022, 1022, . . . are stacked in the thickness direction of the metal meshes 1022. The stack number of the metal meshes 1022 of the metal mesh stacked member 1023 is not particularly limited so long as there are a plurality of layers which are two or more layers, and the metal mesh stacked member 1023 of the evaporation unit structure 1003 has a stacked structure composed of three layers of the metal meshes 1022 for ease of description.

In the evaporation unit structure 1003, the metal mesh stacked member 1023 is sintered to be integrated with the vapor chamber 1010 and to be thermally connected to the vapor chamber 1010. Further, in the evaporation unit structure 1003, the metal mesh stacked member 1023 is sintered, so that the stacked plurality of metal meshes 1022, 1022, 1022, . . . are integrated.

In the evaporation unit structure 1003, the metal mesh stacked member 1023 is formed with the plurality of metal meshes 1022, 1022, 1022, . . . stacked. That is, the plurality of metal meshes 1022, 1022, 1022, . . . , which are separate elements, are sintered in the stacked state, so that the stacked plurality of metal meshes 1022, 1022, 1022, . . . are integrated. Further, since the metal mesh stacked member 1023 has the plurality of metal meshes 1022, 1022, 1022, . . . integrated in the closely stacked state, the metal mesh stacked member 1023 has excellent heat conductive characteristics even if formed with the plurality of metal meshes 1022, 1022, 1022, . . . stacked.

The mesh number and the wire diameter of the respective metal meshes 1022 forming the metal mesh stacked member 1023 may be the same or different among the respective metal meshes 1022. In the evaporation unit structure 1003, the plurality of metal meshes 1022, 1022, 1022, . . . have the same mesh number and wire diameter.

A thickness of the metal mesh stacked member 1023 is determined based on the mesh stack number and the wire diameter of the metal wires and is properly selectable according to use conditions of the evaporation unit structure 1003, properties of the refrigerant in a liquid phase in which the heating source 1100 is to be immersed, and the like. In a case in which the wire diameter is 20 to 100 μm, for example, it is preferable that the mesh stack number should be two or more layers from the viewpoint of reliably obtaining the fine structures, which are advantageous in generating nuclei of boiling, to reliably smooth production of nuclei of boiling, and it is preferable that the mesh stack number should be eight or less layers from viewpoints of making the generated nuclei of boiling easier to leave the boiling promoting part 1020 and reducing flow path resistance of the refrigerant in a liquid phase to smooth supply of the refrigerant in the liquid phase to a lower portion (that is, the metal mesh 1022 located on the vapor chamber 1010 side) of the metal mesh stacked member 1023. Further, it is preferable that the mesh number (the number of wires per inch) in the metal mesh stacked member 1023 should be #50 to #200 similarly to the eighth embodiment example.

Also in the aspect of the evaporation unit structure 1003, because of including the vapor chamber 1010 having the first surface 1011 to which the heating source 1100 immersed in the refrigerant in the liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the metal mesh stacked member 1023, a large number of the fine structures, which are advantageous in generating nuclei of boiling made of the refrigerant in a gas phase, are present in the boiling promoting part 1020, which is the metal mesh stacked member 1023, thus smoothing production of nuclei of boiling. Accordingly, also in the aspect of the evaporation unit structure 1003, it is possible to promote a phase change from a liquid phase to a gas phase of the refrigerant in which the heating source 1100, which is a cooling target, is immersed, and as a result, the cooling characteristics for the heating source 1100 immersed in the refrigerant in the liquid phase are improved.

Further, in the aspect of the evaporation unit structure 1003, since the metal meshes form the metal mesh stacked member 1023 having a plurality of layers of the metal meshes 1022, the boiling promoting part 1020 is increased in thickness to further reliably function as the fine structure, which is advantageous in generating nuclei of boiling, thus enabling production of nuclei of boiling to be further reliably smoothed.

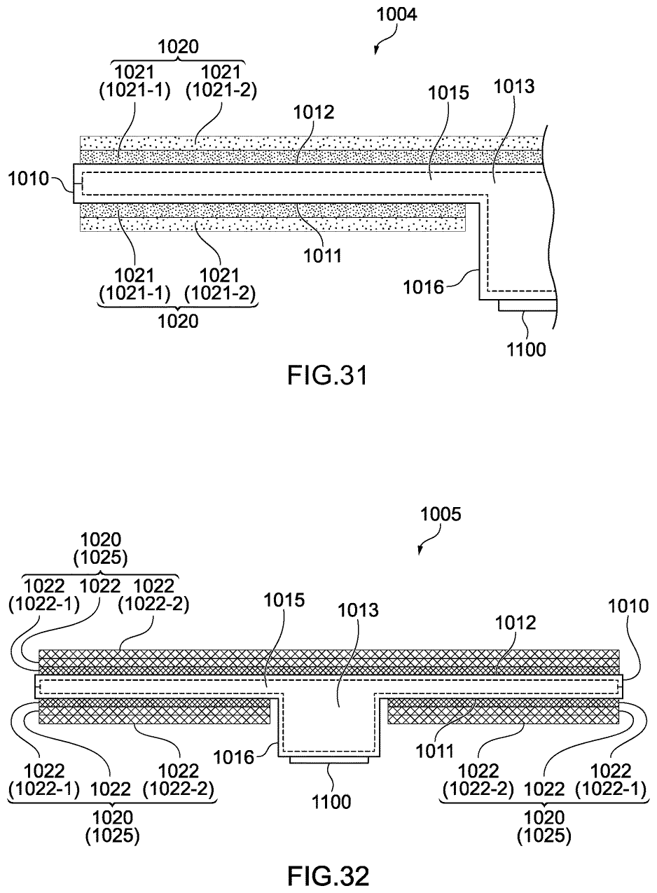

Next, an evaporation unit structure according to a tenth embodiment example of the present disclosure will be described using the accompanying drawings. Since the evaporation unit structure according to the tenth embodiment example has main components in common with the evaporation unit structures according to the seventh to ninth embodiment examples, same components as the components of the evaporation unit structures according to the seventh to ninth embodiment examples are described by using the same reference signs. Note that FIG. 30 is a side view explaining an outline of the evaporation unit structure according to the tenth embodiment example of the present disclosure. FIG. 31 is a magnified side view explaining an outline of a boiling promoting part in the evaporation unit structure according to the tenth embodiment example of the present disclosure.

In the evaporation unit structure 1001 according to the seventh embodiment example, in the sintered body layer 1021 of metal powder, the average particle size of the metal powder is constant regardless of the distance from the vapor chamber 1010, but instead of this, in an evaporation unit structure 1004 according to the tenth embodiment example, the average particle size of the metal powder is smaller at positions increasingly distant from the vapor chamber 1010 in the sintered body layer 1021 of metal powder as illustrated in FIGS. 30 and 31. Since the boiling promoting part 1020 is the sintered body layer 1021, the boiling promoting part 1020 provided on the first surface 1011 and the second surface 1012 of the vapor chamber 1010 has the structure having a plurality of narrow spaces, that is, the structure having roughened portions in which the first surface 1011 and the second surface 1012 are roughened. In the evaporation unit structure 1004, the sintered body layer 1021 functions as the plurality of narrow spaces, that is, the roughened portions.

The sintered body layer 1021 has a first region 1021-1 positioned on the vapor chamber 1010 side and formed of a first metal powder and a second region 1021-2 positioned in the outward direction of the vapor chamber 1010 relative to the first region 1021-1 and formed of a second metal powder. In FIGS. 30 and 31, the first region 1021-1 and the second region 1021-2 are illustrated with clear distinction for the sake of convenience, but they may not be clearly divided as layers. Note that three or more regions formed of metal powders different from one another may be provided.

In the evaporation unit structure 1004, the sintered body layer 1021 is sintered to be integrated with the vapor chamber 1010 and to be thermally connected to the vapor chamber 1010.

The average particle size of the first metal powder forming the first region 1021-1 and the average particle size of the second metal powder forming the second region 1021-2 may be the same or may be different. The evaporation unit structure 1004 is in an aspect in which the average particle size of the first metal powder is smaller than the average particle size of the second metal powder, and in the sintered body layer 1021 of metal powder, the average particle size of the metal powder is smaller at positions increasingly distant from the vapor chamber 1010.

The average particle size of the first metal powder forming the first region 1021-1 is properly selectable according to use conditions of the evaporation unit structure 1004, properties of the refrigerant in a liquid phase in which the heating source 1100 is to be immersed, and the like, and it is preferable that a lower limit value of the average particle size of the first metal powder, for example, should be 10 μm from the viewpoint of reliably obtaining the fine structures, which are advantageous in generating nuclei of boiling. On the other hand, it is preferable that an upper limit value of the average particle size of the first metal powder forming the first region 1021-1 should be 200 μm from the viewpoint of reliably obtaining the boiling promoting part 1020 in which a large number of the fine structures, which are advantageous in generating nuclei of boiling, are present.

The average particle size of the second metal powder forming the second region 1021-2 is properly selectable according to the use conditions of the evaporation unit structure 1004, the properties of the refrigerant in the liquid phase in which the heating source 1100 is to be immersed, and the like, and it is preferable that a lower limit value of the average particle size of the second metal powder, for example, should be 100 μm from viewpoints of making the generated nuclei of boiling easier to leave the boiling promoting part 1020 and reducing flow path resistance of the refrigerant in the liquid phase to smooth supply of the refrigerant in the liquid phase to a lower portion (that is, the first region 1021-1) of the sintered body layer 1021. On the other hand, it is preferable that an upper limit value of the average particle size of the second metal powder forming the second region 1021-2 should be 400 μm from the viewpoint of obtaining the boiling promoting part 1020 in which a large number of the fine structures, which are advantageous in generating nuclei of boiling, are present.

A thickness of the sintered body layer 1021 is properly selectable according to the use conditions of the evaporation unit structure 1004, the properties of the refrigerant in the liquid phase in which the heating source 1100 is to be immersed, and the like, and it is preferable that a lower limit value of the thickness of the sintered body layer 1021, for example, should be 0.2 mm from the viewpoint of reliably obtaining the fine structures, which are advantageous in generating nuclei of boiling, to reliably smooth production of nuclei of boiling. On the other hand, it is preferable that an upper limit value of the thickness of the sintered body layer 1021 should be 0.8 mm from viewpoints of making the generated nuclei of boiling easier to leave the boiling promoting part 1020 and being able to reduce flow path resistance of the refrigerant in the liquid phase to smooth supply of the refrigerant in the liquid phase to a lower portion of the sintered body layer 1021 of metal powder. Further, the thickness of the sintered body layer 1021 may be one that depends on the particle sizes of the metal powders.

Also in the aspect of the evaporation unit structure 1004, because of including the vapor chamber 1010 having the first surface 1011 to which the heating source 1100 immersed in the refrigerant in a liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the sintered body layer 1021 of metal powder, a large number of the fine structures, which are advantageous in generating nuclei of boiling made of the refrigerant in a gas phase, are present in the boiling promoting part 1020, which is the sintered body layer 1021 of metal powder, thus smoothing production of nuclei of boiling. Accordingly, also in the aspect of the evaporation unit structure 1004, it is possible to promote a phase change from a liquid phase to a gas phase of the refrigerant in which the heating source 1100, which is a cooling target, is immersed, and as a result, the cooling characteristics for the heating source 1100 immersed in the refrigerant in the liquid phase are improved.

Further, in the aspect of the evaporation unit structure 1004, since the sintered body layer 1021 having a plurality of regions formed of metal powders different from each other is formed, the boiling promoting part 1020 is increased in thickness to further reliably function as the fine structure, which is advantageous in generating nuclei of boiling, thus enabling production of nuclei of boiling to be further reliably smoothed.

Further, in the aspect of the evaporation unit structure 1004, the sintered body layer 1021 of metal powder has the first region 1021-1 positioned on the vapor chamber 1010 side and formed of the first metal powder and the second region 1021-2 positioned in the outward direction of the vapor chamber 1010 relative to the first region 1021-1 and formed of the second metal powder, and the average particle size of the first metal powder is smaller than the average particle size of the second metal powder, and in the sintered body layer 1021 of metal powder, the average particle size of the metal powder is smaller at positions increasingly distant from the vapor chamber 1010. Accordingly, the first region 1021-1 further reliably functions as the fine structure, which is advantageous in generating nuclei of boiling. Further, the second region 1021-2 has a structure in which the generated nuclei of boiling are easy to leave the boiling promoting part 1020 while contributing to production of nuclei of boiling and can reduce flow path resistance of the refrigerant in the liquid phase to smooth supply of the refrigerant in the liquid phase to the first region 1021-1. From the foregoing, in the aspect of the evaporation unit structure 1004, it is possible to further smooth production of nuclei of boiling to further promote a phase change from a liquid phase to a gas phase of the refrigerant in contact with the boiling promoting part 1020.

Next, an evaporation unit structure according to an eleventh embodiment example of the present disclosure will be described using the accompanying drawings. Since the evaporation unit structure according to the eleventh embodiment example has main components in common with the evaporation unit structures according to the seventh to tenth embodiment examples, same components as the components of the evaporation unit structures according to the seventh to tenth embodiment examples are described by using the same reference signs. Note that FIG. 32 is a side view explaining an outline of the evaporation unit structure according to the eleventh embodiment example of the present disclosure.

In the evaporation unit structure 1003 according to the nineth embodiment example, the plurality of metal meshes 1022, 1022, 1022, . . . forming the metal mesh stacked member 1023 all have the same mesh number, but instead of this, in an evaporation unit structure 1005 according to the eleventh embodiment example, the plurality of metal meshes 1022, 1022, 1022, . . . forming a metal mesh stacked member 1025 which is the boiling promoting part 1020 have different mesh numbers as illustrated in FIG. 32. Since the boiling promoting part 1020 is the metal mesh stacked member 1025, the boiling promoting part 1020 provided on the first surface 1011 and the second surface 1012 of the vapor chamber 1010 has the structure having a plurality of narrow spaces, that is, the structure having roughened portions in which the first surface 1011 and the second surface 1012 are roughened. In the evaporation unit structure 1005, the metal mesh stacked member 1025 functions as the plurality of narrow spaces, that is, the roughened portions.

The evaporation unit structure 1005 is in an aspect in which the metal mesh stacked member 1025 has a first metal mesh 1022-1 which is positioned on the vapor chamber 1010 side and which contacts the vapor chamber 1010 and a second metal mesh 1022-2 which is positioned in the outward direction of the vapor chamber 1010 relative to the first metal mesh 1022-1 and which forms an outermost layer of the boiling promoting part 1020, in which the mesh number of the first metal mesh 1022-1 is larger than the mesh number of the second metal mesh 1022-2 (that is, an opening of the first metal mesh 1022-1 is smaller than an opening of the second metal mesh 1022-2). Note that the evaporation unit structure 1005 is in an aspect in which the mesh number of the metal mesh 1022 positioned between the first metal mesh 1022-1 and the second metal mesh 1022-2 is smaller than the mesh number of the first metal mesh 1022-1 and larger than the mesh number of the second metal mesh 1022-2.

The mesh number of the first metal mesh 1022-1 is properly selectable according to use conditions of the evaporation unit structure 1005, properties of the refrigerant in the liquid phase in which the heating source 1100 is to be immersed, and the like and is preferably #200 or less from the viewpoint of reliably obtaining the fine structures, which are advantageous in generating nuclei of boiling, for example. On the other hand, it is preferable that the mesh number of the first metal mesh 1022-1 should be #50 or more from the viewpoint of reliably obtaining the boiling promoting part 1020 in which a large number of the fine structures, which are advantageous in generating nuclei of boiling, are present.

The mesh number of the second metal mesh 1022-2 is properly selectable according to the use conditions of the evaporation unit structure 1005, the properties of the refrigerant in the liquid phase in which the heating source 1100 is to be immersed, and the like and is preferably #200 or less from viewpoints of making the generated nuclei of boiling easier to leave the boiling promoting part 1020 and reducing flow path resistance of the refrigerant in the liquid phase to smooth supply of the refrigerant in the liquid phase to a lower portion (that is, the first metal mesh 1022-1) of the metal mesh stacked member 1025, for example. On the other hand, it is preferable that the mesh number of the second metal mesh 1022-2 should be #50 or more from the viewpoint of obtaining the boiling promoting part 1020 in which a large number of the fine structures, which are advantageous in generating nuclei of boiling, are present.

The thickness of the metal mesh stacked member 1025 is determined based on the mesh stack number and the wire diameter of the metal wires, and is properly selectable according to the use conditions of the evaporation unit structure 1005, the properties of the refrigerant in the liquid phase in which the heating source 1100 is to be immersed, and the like. In a case in which the wire diameter is 20 to 100 μm, for example, it is preferable that the mesh stack number should be two or more layers from the viewpoint of reliably obtaining the fine structures, which are advantageous in generating nuclei of boiling, to reliably smooth production of nuclei of boiling. On the other hand, in the case in which the wire diameter is 20 to 100 μm, it is preferable that the mesh stack number should be eight or less layers from viewpoints of making the generated nuclei of boiling easier to leave the boiling promoting part 1020 and reducing flow path resistance of the refrigerant in the liquid phase to smooth supply of the refrigerant in the liquid phase to the lower portion (that is, the first metal mesh 1022-1) of the metal mesh stacked member 1025.

Also in the aspect of the evaporation unit structure 1005, because of including the vapor chamber 1010 having the first surface 1011 to which the heating source 1100 immersed in the refrigerant in the liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the metal mesh stacked member 1025, a large number of the fine structures, which are advantageous in generating nuclei of boiling made of the refrigerant in a gas phase, are present in the boiling promoting part 1020, which is the metal mesh stacked member 1025, thus smoothing production of nuclei of boiling. Accordingly, also in the aspect of the evaporation unit structure 1005, it is possible to promote a phase change from a liquid phase to a gas phase of the refrigerant in which the heating source 1100, which is a cooling target, is immersed, and as a result, the cooling characteristics for the heating source 1100 immersed in the refrigerant in the liquid phase are improved.

Further, in the aspect of the evaporation unit structure 1005, since the metal mesh stacked member 1025 has the first metal mesh 1022-1 positioned on the vapor chamber 1010 side and the second metal mesh 1022-2 positioned in the outward direction of the vapor chamber 1010 relative to the first metal mesh 1022-1, in which the mesh number of the first metal mesh 1022-1 is larger than the mesh number of the second metal mesh 1022-2, the first metal mesh 1022-1 is a structure finer than the second metal mesh 1022-2. Accordingly, the first metal mesh 1022-1 further reliably functions as the fine structure, which is advantageous in generating nuclei of boiling. Further, the second metal mesh 1022-2 has the structure in which the generated nuclei of boiling are easy to leave the boiling promoting part 1020 while contributing to production of nuclei of boiling, and can reduce flow path resistance of the refrigerant in the liquid phase to smooth supply of the refrigerant in the liquid phase to the first metal mesh 1022-1. From the foregoing, in the aspect of the evaporation unit structure 1005, it is possible to further smooth production of nuclei of boiling to further promote a phase change from a liquid phase to a gas phase of the refrigerant in contact with the boiling promoting part 1020.

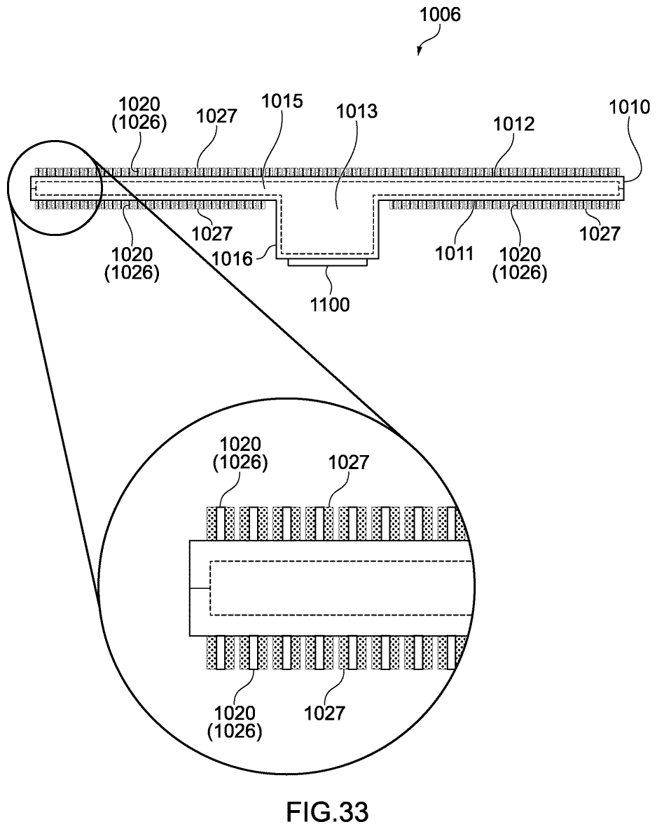

Next, an evaporation unit structure according to a twelfth embodiment example of the present disclosure will be described using the accompanying drawings. Since the evaporation unit structure according to the twelfth embodiment example has main components in common with the evaporation unit structures according to the seventh to eleventh embodiment examples, same components as the components of the evaporation unit structures according to the seventh to eleventh embodiment examples are described by using the same reference signs. Note that FIG. 33 is a side view explaining an outline of the evaporation unit structure according to the twelfth embodiment example of the present disclosure.

In the evaporation unit structures according to the seventh to eleventh embodiment examples, the boiling promoting part 1020 is formed by the sintered body layer 1021 of metal powder or the metal meshes 1022, but instead of this, in an evaporation unit structure 1006 according to the twelfth embodiment example, the boiling promoting part 1020 has a structure having a plurality of protruding portions 1026, 1026, 1026, . . . as illustrated in FIG. 33. Since the boiling promoting part 1020 is the plurality of protruding portions 1026, 1026, 1026, . . . , the boiling promoting part 1020 provided on the first surface 1011 and the second surface 1012 of the vapor chamber 1010 has the structure having a plurality of narrow spaces, that is, the structure having roughened portions in which the first surface 1011 and the second surface 1012 are roughened. In the evaporation unit structure 1006, voids among the plurality of protruding portions 1026, 1026, 1026, . . . function as the plurality of narrow spaces, that is, the roughened portions.

The protruding portion 1026 is not particularly limited in shape so long as it is one that protrudes from a flat surface, but may have a prism shape such as columnar shape or a regular polygonal prism shape, for example, and a plate shape provided in a standing manner (a shape extending in one direction orthogonal to a protruding direction), and the like are cited. Further, the protruding portion 1026 may protrude so as to be orthogonal to a flat surface to be a reference, and the protruding direction may change to some degree. As described, a skived fin in which plate-like portions protrude while curving is also included in the protruding portion 1026. Note that a plurality of slits may be formed in a predetermined flat surface to use a portion between adjacent slits as the protruding portion.

Further, in the evaporation unit structure 1006, a surface of the protruding portion 1026 further has a roughened portion 1027. As the roughened portion 1027, a sintered body of metal powder is cited, for example. That is, as the boiling promoting part 1020, an aspect in which surfaces of the plurality of protruding portions 1026, 1026, 1026, . . . are covered by a sintered body of metal powder is cited.

Also in the aspect of the evaporation unit structure 1006, because of including the vapor chamber 1010 having the first surface 1011 to which the heating source 1100 immersed in the refrigerant in a liquid phase (for example, the primary refrigerant 1201 in the cooling device 1210) is thermally connected and the second surface 1012 opposite the first surface 1011 as well as the boiling promoting part 1020, which is provided on the first surface 1011 and the second surface 1012 of the vapor chamber 1010, which contacts the refrigerant in the liquid phase, and which is the plurality of protruding portions 1026, 1026, 1026, . . . , a large number of the fine structures, which are advantageous in generating nuclei of boiling made of the refrigerant in a gas phase, are present in the boiling promoting part 1020, which is the plurality of protruding portions 1026, 1026, 1026, . . . , thus smoothing production of nuclei of boiling. Accordingly, also in the aspect of the evaporation unit structure 1006, it is possible to promote a phase change from a liquid phase to a gas phase of the refrigerant in which the heating source 1100, which is a cooling target, is immersed, and as a result, the cooling characteristics for the heating source 1100 immersed in the refrigerant in the liquid phase are improved.

Further, in the aspect of the evaporation unit structure 1006, since the boiling promoting part 1020 has the plurality of protruding portions 1026, 1026, 1026, . . . , voids among the plurality of protruding portions 1026, 1026, 1026, . . . reliably function as the fine structures, which are advantageous in generating nuclei of boiling, thus enabling production of nuclei of boiling to be further smoothed.

Further, in the aspect of the evaporation unit structure 1006, since the surface of the protruding portion 1026 further has the roughened portion 1027, not only the voids among the plurality of protruding portions 1026, 1026, 1026, . . . , but also the roughened portions 1027 reliably function as the fine structures, which are advantageous in generating nuclei of boiling, thus enabling production of nuclei of boiling to be further smoothed.

Next, another embodiment example of the evaporation unit structure of the present disclosure will be described. In the evaporation unit structures according to the above-described respective embodiment examples, the boiling promoting part 1020 is provided on the first surface 1011 and the second surface 1012 of the vapor chamber 1010, but instead of this, the boiling promoting part 1020 may be provided on the first surface 1011 or the second surface 1012 of the vapor chamber 1010.

Further, in the evaporation unit structures according to the seventh to twelfth embodiment examples, the single heating source 1100 is thermally connected to the single evaporation unit structure 1001, but a plurality of heating sources may be thermally connected to a single evaporation structure unit. At this time, the plurality of heating sources may be thermally connected to a single surface of a vapor chamber, or may be thermally connected to different surfaces, respectively. Further, in the case in which heating sources are thermally connected to a pair of opposite surfaces of the vapor chamber, respectively, and in a case in which one of the pair of surfaces is a first surface, the other is a second surface.

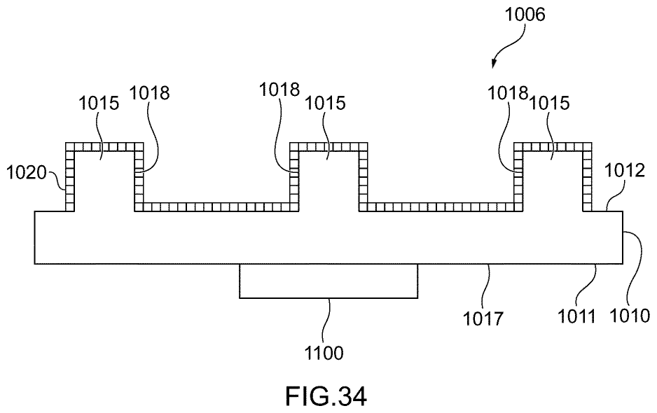

Further, in the evaporation unit structures according to the seventh to twelfth embodiment examples, the protruding portion 1016 is provided on the first surface 1011 to which the heating source 1100 is thermally connected, but protruding portions may be provided on both the first surface and the second surface, or a protruding portion may be provided only on the second surface, or a protruding portion may not be provided on either of the first surface and the second surface. As another embodiment example of the evaporation unit structure of the present disclosure, a structure in which protruding portions 1018 are provided only on the second surface 1012 is illustrated in FIG. 34.

In the embodiment example illustrated in FIG. 34, a protruding portion is not provided on the first surface 1011, but the entire first surface 1011 is the flat surface portion 1017, and the heating source 1100 contacts and is thermally connected to the flat surface portion 1017. A plurality of (three in the illustrated example) protruding portions 1018 are formed on the second surface 1012. These protruding portions 1018 do not contact the heating source 1100, unlike the protruding portion 1016 in the seventh to twelfth embodiment examples. Further, internal spaces of the protruding portions 1018 form part of the vapor flow path 1015 through which the working fluid in a gas phase flows, enabling the working fluid to flow.

Further, in the embodiment example illustrated in FIG. 34, the boiling promoting part 1020 is not provided on the first surface 1011, but the boiling promoting part 1020 is provided on the second surface 1012 so as to cover the protruding portions 1018. The protruding portions 1018 enable the working fluid to flow in the inside of the protruding portions 1018 as described above, and are clearly distinguished from a protruding portion on the boiling promoting part 1020 even in the case (for example, the twelfth embodiment example) in which the protruding portion is formed on the boiling promoting part 1020. By thus providing the protruding portions 1018 on the second surface 1012, it is possible to make the surface area of the second surface 1012 larger to make the area of a region in which the boiling promoting part 1020 is provided larger, so that the cooling characteristics for the heating source 1100 are improved. Further, since the working fluid can flow in the inside of the protruding portions 1018, heat transmission efficiency between the working fluid and the boiling promoting part 1020 in the protruding portions 1018 is improved.

The evaporation unit structure of the present disclosure can promote a phase change from a liquid phase to a gas phase of a refrigerant in which a heating source that is a cooling target is immersed, and is thus highly useful particularly in fields in which heating elements such as electronic components used in a data center and the like have increased in heat generation amount.

What is claimed is:

1. An evaporation unit structure comprising:
a base plate having a first surface and a second surface, a heating source immersed in a refrigerant in a liquid phase being thermally connected to the second surface; and
a metal mesh stacked member thermally connected to the first surface and/or the second surface of the base plate and having a plurality of layers of a metal mesh, wherein
a metal wire forming the metal mesh has a flat portion.

2. The evaporation unit structure according to claim 1, wherein the flat portion of the metal wire is a pressure-welded portion of the plurality of layers of the metal mesh.

3. The evaporation unit structure according to claim 1, wherein
the metal mesh is a screen mesh in which a plurality of first metal wires forming warps and a plurality of second metal wires forming wefts alternately cross up and down, and
the plurality of first metal wires and the plurality of second metal wires have the flat portion.

4. The evaporation unit structure according to claim 1, wherein the metal mesh stacked member is sintered to be thermally connected to the base plate.

5. The evaporation unit structure according to claim 1, wherein
the first surface is opposite the second surface, and
the metal mesh stacked member is thermally connected to the first surface.

6. The evaporation unit structure according to claim 1, wherein the metal mesh stacked member is formed with a plurality of metal meshes, each being the metal mesh, stacked.

7. The evaporation unit structure according to claim 1, wherein a mesh number of the metal mesh forming the metal mesh stacked member is 200/2.54 cm or more.

8. The evaporation unit structure according to claim 1, wherein a mesh number of the metal mesh forming the metal mesh stacked member is 300/2.54 cm or more.

9. The evaporation unit structure according to claim 1, wherein the metal mesh stacked member is formed by two or more layers and ten or less layers of the metal mesh.

10. The evaporation unit structure according to claim 1, wherein the metal mesh stacked member or a plurality of metal mesh stacked members, each being the metal mesh stacked member, is/are provided along an extending direction of the first surface.

11. The evaporation unit structure according to claim 1, wherein the metal mesh stacked member or a plurality of metal mesh stacked members, each being the metal mesh stacked member, is/are provided along an extending direction of the second surface.

12. The evaporation unit structure according to claim 1, wherein the base plate is a vapor chamber including a container in which a cavity portion is formed inside, a working fluid enclosed in the cavity portion, and a vapor flow path which is provided in the cavity portion and through which the working fluid in a gas phase flows.
